(19) United States
(12) Patent Application Publication
(10) Pub. No.: US 2012/0160290 A1
(43) Pub. Date: Jun. 28, 2012

(54) THERMOELECTRIC SYSTEM AND METHOD OF OPERATING SAME

(75) Inventors: Gang Chen, Carlisle, MA (US); Zhifeng Ren, Newton, MA (US); Bed Poudel, Brighton, MA (US); Aaron Bent, North Reading, MA (US)

(73) Assignee: GMZ Energy, Inc., Waltham, MA (US)

(21) Appl. No.: 13/322,280

(22) PCT Filed: May 28, 2010
(86) PCT No.: PCT/US10/36607

§ 371 Date: Mar. 8, 2012

Related U.S. Application Data
(60) Provisional application No. 61/181,899, filed on May 28, 2009.

(51) Int. Cl. H01L 35/02; H01L 35/30

(52) U.S. Cl. 136/206

(57) ABSTRACT

An apparatus includes an evacuated enclosure which comprises a tubular member extending along a longitudinal axis, a radiation absorber disposed in the enclosure and having a front surface and a back surface, the front surface being adapted for exposure to solar radiation so as to generate heat, at least one thermoelectric converter disposed in the enclosure and thermally coupled to the absorber, the converter having a high-temperature end to receive at least a portion of the generated heat, such that a temperature differential is achieved across the at least one thermoelectric converter, a support structure disposed in the enclosure coupled to a low-temperature end of the thermoelectric converter, where the support structure removes heat from a low-temperature end of the thermoelectric converter, and a heat conducting element extending between the support structure and the evacuated enclosure and adapted to transfer heat from the support structure to the enclosure. The absorber, the at least one thermoelectric converter, and the support structure are arranged as a planar unit located within the tubular member.

### FIELD OF THE INVENTION

The present invention relates generally to methods and devices for the conversion of solar energy. Specifically, the present invention relates to methods and devices that optionally combine solar thermoelectric conversion with solar thermal conversion.

### BACKGROUND OF THE INVENTION

Solar energy converters include solar electric, solar fuel, and solar thermal converters. Solar electric converters convert solar energy into electrical energy directly, with solar photovoltaic (PV) cells, or indirectly, with solar thermal to electric converters Solar fuel converters extract fuels from a solution using electrolysis, where the electrical energy driving the electrolysis step comes directly from PV cells. Solar thermal converters convert solar energy into thermal energy or heat.

Both PV cells and solar thermal converters are used residentially, with hot water systems taking the larger market share. Some countries have focused on roof-top PV cells, while other countries have widespread use of roof-top hot-water systems.

In addition to functioning strictly as hot water systems, solar thermal converters have been used to generate electrical energy by driving mechanical heat engines with steam generated from the solar thermal converter. In a solar thermal converter, one or more fluid conduits are provided in direct thermal contact with a solar radiation absorbing surface. The surface absorbs solar radiation and transfers heat to the conduits. The transferred heat raises the temperature of the fluid, such as oil, liquid salt or water flowing through the conduit. The heated fluid is then used in a power generator, such as a steam driven power generator to generate electricity. The term “fluid”, as used herein includes both liquid or gases.

In contrast, thermoelectric power generation relies on the Seebeck effect in solid materials to convert thermal energy into electricity. The theoretical energy conversion efficiency ηₜₑ of a thermoelectric device operating between a hot-side temperature Tₕ and a cold-side temperature T_{c} is given by:

$${n}_{te} = ( 1 - \frac{{T}_{c}}{{T}_{h}} ) \frac{\sqrt{1 + Z T} - 1}{\sqrt{1 + Z T} + \frac{{T}_{c}}{{T}_{h}}} \qquad ( 1 )$$

where the first factor, in parenthesis, is the Carnot efficiency and the second factor, the fractional component, is determined by the thermoelectric figure of merit Z and the average temperature T=0.5(Tₕ+T_{c}) of the thermoelectric materials.

The thermoelectric figure of merit Z is related to the Seebeck coefficient S of the thermoelectric material by the following equation:

Z=S²σ/k (2)

where σ is the electrical conductivity and k is thermal conductivity of the thermoelectric material.

Thermoelectric devices operating between Tₕ=500 K and Tₑ=300 K, with a dimensionless figure of merit ZT between 1-2, can have an efficiencies of 9-14%. Increasing the temperature difference between the hot-side and cold-side to Tₕ=1000 K and T_{c}=300 K improves efficiencies of the thermoelectric device to 17-25%. In the past, the maximum ZT of thermoelectric materials has been limited to about 1, yielding thermoelectric power generators with low efficiencies. As an example, one prior art system uses Si₈₀Ge₂₀ alloys as a thermoelectric material in thermoelectric generators and radioisotopes as a heat source, with the system operating at a maximum temperature of 900° C. and a thermal energy to electricity energy conversion efficiency of 6%.

More recently, with the introduction of new thermoelectric materials, researchers have achieved thermal energy to electrical energy conversion efficiencies of 12-14%. A large increase in ZT has been reported using Bi₂Te₃/Sb₂Te₃ superlattices and PbTe/PbSe superlattices, and using nanostructured bulk materials. A ZT value as high as 3.5 has been reported in PbTe/PbSe superlattices at 300° C.

### SUMMARY

An apparatus includes an evacuated enclosure which comprises a tubular member extending along a longitudinal axis, a radiation absorber disposed in the enclosure and having a front surface and a back surface, the front surface being adapted for exposure to solar radiation so as to generate heat, at least one thermoelectric converter disposed in the enclosure and thermally coupled to the absorber, the converter having a high-temperature end to receive at least a portion of the generated heat, such that a temperature differential is achieved across the at least one thermoelectric converter, a support structure disposed in the enclosure coupled to a low-temperature end of the thermoelectric converter, wherein the support structure removes heat from a low-temperature end of the thermoelectric converter, and a heat conducting element extending between the support structure and the evacuated enclosure and adapted to transfer heat from the support structure to the enclosure. The absorber, the at least one thermoelectric converter, and the support structure are arranged as a planar unit located within the tubular member.

### BRIEF DESCRIPTION OF THE DRAWINGS

The foregoing and other objects, features, and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating principles of the invention.

FIG. 1 is a side-view depiction of a flat-panel configuration of a solar-electrical generator module, consistent with some embodiments of the present invention.

FIG. 2 depicts a graph of the reflectivity of different polished copper surfaces as a function of wavelength, allowing deduction of the emissivity, consistent with some embodiments of the present invention.

FIG. 3 is a side-view depiction of a flat-panel configuration of a solar-electrical generator module with one p-type leg and one n-type leg, consistent with some embodiments of the present invention.

FIG. 4 is a side-view depiction of several flat-panel modules enclosed in an isolated environment, consistent with some embodiments of the present invention.

FIG. 5A is a side-view depiction of a solar-electrical generator using a lens as a solar concentrator, consistent with some embodiments of the present invention.

FIG. 5B is a side-view depiction of a solar-electrical generator using two reflective structures as a solar concentrator, consistent with some embodiments of the present invention.

FIG. 5C is a side-view depiction of a solar-electrical generator using a transmissive lens as a solar concentrator that contacts a solar capture structure, consistent with some embodiments of the present invention.

FIG. 6A is a side-view depiction of a solar-electrical generator utilizing a solar concentrator and a thermoelectric converter in a horizontal position, consistent with some embodiments of the present invention.

FIG. 6B is a side-view depiction of a solar-electrical generator utilizing a solar concentrator and two thermoelectric converters in a horizontal position stacked on top of each other, consistent with some embodiments of the present invention.

FIG. 6C is a side-view depiction of a solar-electrical generator utilizing a solar concentrator in a mushroom shape and a thermoelectric converter in a horizontal position, consistent with some embodiments of the present invention.

FIG. 7 is a side-view depiction of a solar-electrical generator utilizing a plurality of reflective surfaces arranged in a trough design as a plurality of solar concentrators, consistent with some embodiments of the present invention.

FIG. 8A is a perspective view depiction of a solar-electrical generator utilizing a plurality of lens structures as a plurality of solar concentrators, consistent with some embodiments of the present invention.

FIG. 8B is a side view depiction of the solar-electrical generator shown in FIG. 8A.

FIG. 9 is a side-view depiction of a solar-electrical generator utilizing a plurality of lens structures as a plurality of solar concentrators and a single solar thermoelectric generator having grouped converters, consistent with some embodiments of the present invention.

FIG. 10A is a side-view depiction of a solar-electrical generator using a flat Fresnel lens as a solar concentrator and a barrier structure enclosing a thermoelectric converter in an isolated environment, consistent with some embodiments of the present invention.

FIG. 10B is a side-view depiction of a solar-electrical generator using a curved Fresnel lens as a solar concentrator and a barrier structure enclosing a thermoelectric converter in an isolated environment, consistent with some embodiments of the present invention.

FIG. 10C is a side-view depiction of a solar-electrical generator using two reflective surfaces to concentrate solar radiation onto a barrier structure enclosing a thermoelectric converter in an isolated environment, consistent with some embodiments of the present invention.

FIG. 11 is a side-view depiction of a solar-electrical generator using a parabolic reflective surface to concentrate solar radiation onto a barrier structure enclosing a converter coupled to a capture structure having a protruding element, consistent with some embodiments of the present invention.

FIG. 12 is a side-view depiction of a support structure coupled to a fluid-based heat transfer system for removing heat from the support structure, consistent with some embodiments of the present invention.

FIG. 13A provides a schematic of a prototype solar-electrical generator, consistent with some embodiments of the present invention.

FIG. 13B provides a graph of power versus load resistance tested in the prototype solar-electrical generator represented in FIG. 13A.

FIG. 13C provides a graph of efficiency versus load resistance tested consistent with the data shown in FIG. 13B.

FIGS. 14A-14D provide three dimensional views of a solar thermal-thermoelectric (STTE) converter elements in accordance with embodiments of the present invention.

FIGS. 15 and 16 are plots of ZT values versus temperature for several thermoelectric converter materials vs. temperature.

FIGS. 17A and 17B are schematic depictions of two possible nanostructure thermoelectric materials composites for thermoelectric materials.

FIG. 18A shows TEM images for Bi₂Te₃ and Bi₂Se₃ nanoparticles.

FIG. 18B shows TEM images for compacted samples from Bi₂Te₃ based alloy nanopowder.

FIG. 19A-19E illustrate temperature dependence of electrical conductivity, Seebeck coefficient, power factor, thermal conductivity and ZT value, respectively, of SiGe nanocomposite materials.

FIGS. 20A-20C are schematic three dimensional views of 2D and 3D solar energy flux concentrators.

FIG. 21A illustrates a series of trough concentrators and FIG. 21B illustrates a fluid conduit used in power plants populated by solar thermo-thermoelectric converters.

FIG. 22 provides a side cross sectional view of an individual solar thermo-thermoelectric converter cell.

FIGS. 23A-C illustrate ZT value dependence of efficiency, thermal concentration ratio and hot size temperature for thermoelectric devices according to embodiments of the invention.

FIG. 24 is a plot of expected electrical and water heating efficiencies as a function of ZT value for a hot water heating system of an embodiment of the invention.

FIG. 25 is a plot of expected electrical and heating efficiencies as a function of ZT value for a system of an embodiment of the invention.

FIG. 26A is a perspective view of a thermoelectric solar conversion module.

FIG. 26B is a detailed front view of the module of FIG. 26A.

FIG. 27A is an exploded three dimensional view of a thermoelectric solar conversion module featuring standoff supports.

FIG. 27B is side view of a thermoelectric solar conversion module featuring standoff supports. An inset show a detailed top view of a stand off.

FIG. 28A is side view of a thermoelectric solar conversion module.

FIG. 28B is bottom view of a segment of the thermoelectric solar conversion module of FIG. 28A.

FIG. 28C is top view of a segment of the thermoelectric solar conversion module of FIG. 28A.

FIG. 29A is a side view of a solar conversion module featuring a tubular enclosure and a planar thermoelectric device.

FIG. 29B is a front view of a solar conversion module featuring a tubular enclosure and a planar thermoelectric device.

FIGS. 30A through 30F are front views of solar conversion modules featuring a tubular enclosure, a planar thermoelectric device, and various types of heat conducting elements.

FIG. 31A is a front view of solar conversion module featuring a tubular enclosure, a planar thermoelectric device, and a heat conducting element having an optical concentration element.

FIG. 31B is a front view of solar conversion module featuring a tubular enclosure, a planar thermoelectric device, and a heat conducting element having an optical concentration element.

FIG. 32A is a side view of solar conversion module featuring a tubular enclosure, a planar thermoelectric device, and a heat pipe.

FIG. 32B is a top view of solar conversion module featuring a tubular enclosure, a planar thermoelectric device, and a heat pipe.

FIG. 33 illustrates the operation of a heat pipe.

FIG. 34 is a top view of a heating system including a solar conversion module featuring a tubular enclosure, a planar thermoelectric device, and a heat pipe in contact with a building hot water pipe.

FIG. 35 is a top view of a building heating system including a solar conversion module featuring a tubular enclosure, a planar thermoelectric device, and a heat pipe.

FIG. 36 is a front view of a solar conversion module featuring a tubular enclosure and a cylindrical thermoelectric device.

FIG. 37 is a side view of a solar conversion module featuring a tubular enclosure and a thermoelectric device located outside of the enclosure.

### DETAILED DESCRIPTION OF THE PREFERRED EMBODIMENTS

The present inventors realized that solar energy efficiency would be improved if the solar thermoelectric device was integrated into devices of the types described herein. In some embodiments, a solar thermoelectric device positioned in an evacuated enclosure may benefit from a heat transfer element providing thermal communication between the cold side of the thermoelectric device and the enclosure to act as a heat sink. In various embodiments, solar conversion modules exhibit a solar conversion efficiency of 4% or greater.

The present inventors also realized that solar energy conversion system efficiency would be improved if the solar thermoelectric device was integrated with a solar thermal conversion device, such as a solar fluid heating device or a solar thermal to electrical plant. A solar thermal to electrical conversion plant (which can be referred to simply as a “solar thermal plant”) includes but is not limited to Rankine based and Stirling based plants, and includes trough, tower, and dish shaped plants, as will be described below. Such a system co-generates solar electrical energy and solar thermal energy. Specifically, if the solar thermal conversion device is a solar fluid heating system, such as a solar hot water heating system, then the system can provide cogeneration of electricity using the solar thermoelectric device, and hot water for a facility, such as a building, using the solar hot water system.

In one embodiment of the invention, the inventors also realized that in a combination system that includes both the thermoelectric device and the solar fluid heating system, the fluid conduit should be physically separated and thermally decoupled from the solar radiation absorbing surface by the poorly thermally conducting thermoelectric material legs or posts, so that a proper temperature difference can be created across the thermoelectric legs or posts, and consequently, between the solar absorbing surface and the fluid conduits. This system configuration is opposite from the prior art system containing only the solar fluid heating device in which the fluid conduit is placed in thermal contact with the solar radiation absorbing surface for optimum transfer of the heat from the absorbing surface to the fluid.

The thermoelectric device generates electricity due to a temperature difference between its cold side and its hot side which is in thermal contact and optionally in physical contact with the absorbing surface. As used herein, the terms thermal contact or thermal integration between two surfaces means that heat is efficiently transferred between the surfaces either because the surfaces are in direct physical contact or are not in direct contact but are connected by a thermally conductive material, such as metal, etc.

The inventors realized that if the fluid conduit of the solar thermal conversion device is also placed in thermal contact with the solar absorber (also referred to as a solar absorbing surface), then the fluid conduit will act as a heat sink. This will significantly reduce the temperature difference between the hot and cold sides of the thermoelectric device and would thus significantly decrease the efficiency of the thermoelectric device.

In contrast, if the fluid conduit is placed in thermal contact with the cold side of the thermoelectric device, then the fluid conduit will act as a heat sink and increase the temperature difference between the hot and cold sides of the thermoelectric device and thus improve the efficiency of the thermoelectric device. Since the thermoelectric converters (e.g., semiconductor legs or posts) of the thermoelectric device are poor thermal converters, the fluid conduit is not in thermal contact (i.e., not thermally integrated) with the solar absorber surface. Thus, the fluid conduit does not act as a heat sink for the solar absorber surface and does not interfere with the operation of the thermoelectric device.

Furthermore, the cold side of the thermoelectric device is still sufficiently warm (i.e., is above room temperature) to heat the fluid, such as water or oil, inside the fluid conduit to a desired temperature. For example, for a hot water heating system, the cold side of the thermoelectric device may be maintained at a temperature of about 50 to about 150° C., such as for example less than 100° C., preferably 30 to 70° C., which is sufficiently high to heat water to about 40 to about 150° C. for home, commercial or industrial use. Thus, the water heated by the cold side of the thermoelectric device is provided from the fluid conduit into the facility as hot water for various uses, such as hot water for showers or sinks, hot water or steam for use in radiators for room heating, etc. Alternatively, if the fluid, such as oil or salt is sufficiently heated, then it may be used in a thermal power plant to generate electricity. For example, the oil or salt may be heated above its boiling point. Alternatively, the oil or salt may be heated below its boiling point, but to a sufficiently high temperature so that it is used to heat water into steam, which is feed into steam turbine to generate electricity.

An optional solar energy flux collector and/or concentrator may also be provided above the solar absorber to collect and/or concentrate solar energy. Imaging and non-imaging optical methods that concentrate the incident solar energy flux may be used to collect and concentrate the solar energy flux to generate a higher solar energy flux density. This method of increasing energy flux is termed optical concentration. The hot side temperature depends on optical and thermal concentration ratio, as will be described in more detail below.

An optional selective surface passes solar energy in the visible (V) and ultra-violet (UV) spectra to a solar absorber (i.e., a solar absorbing surface). The solar absorber converts the solar radiation to thermal energy (i.e., heat). The selective surface retains heat in the solar absorber by limiting infrared radiation. An optional set of conduits with narrowing cross-sections conduct the thermal energy stored in the solar absorber to a set of thermoelectric converters (such as a set of alternating p-type and n-type semiconductor legs or posts), concentrating the absorbed thermal energy to the thermoelectric legs. With respect to the term “narrowing cross sections”, it should be noted that in a flat panel concentrator, preferably there is no physical narrowing of the thickness of the absorber. However, heat transfers to the thermoelectric legs in a nearly concentric fashion, and hence heat transfer area is actually changing. In other configurations the narrowing cross section may comprise a physically narrowing cross-section. Thus, the converters are in thermal contact with the solar absorber. The thermal energy concentration via heat conduction is termed thermal concentration. The resulting thermal energy flux density channeled through the set of thermoelectric converters, is determined by the cross-section, spacing, and length of the thermoelectric converters.

The energy flux flowing into thermoelectric devices can be increased via a combination of the optical concentration and thermal concentration, depending on the desirable hot and cold side temperature of the thermoelectric legs, on the properties of selective absorbers.

The thermoelectric converters convert a portion of the stored thermal energy into electrical energy. The thermoelectric converters themselves can be made from a variety of bulk materials and/or nanostructures. The converters preferably comprise a plural sets of two converter elements—one p-type and one n-type semiconductor converter post or leg which are electrically connected to form a p-n junction. The thermoelectric converter materials can comprise, but are not limited to, one of: Bi₂Te₃: Bi₂Te₃₋ₓSeₓ (n-type)/BiₓSe₂₋ₓTe₃ (p-type), SiGe (e.g., Si₈₀Ge₂₀) PbTe, skutterudites, Zn₃Sb₄, AgPbₘSbTe₂₊ₘ, Bi₂Te₃/Sb₂Te₃ quantum dot superlattices (QDSLs), PbTe/PbSeTe QDSLs, PbAgTe, and combinations thereof. The materials may comprise compacted nanoparticles or nanoparticles embedded in a bulk matrix material.

Optionally, a base comprising heat sink material is located between the cold side of the thermoelectric converters of the thermoelectric device and the fluid conduit. The base may comprise a metal or other highly thermally conductive material to provide a thermal contact between the thermoelectric converters and the fluid pipe. Heat associated with unconverted thermal energy conducts from the cold side of the thermoelectric device though the base to the fluid conduit. An optional heat exchanger may be located in the base. The fluid from the fluid conduit passes through the heat exchanger to receive heat from the thermoelectric device. The heat exchanger may comprise thermally conducting plates, a set of thermally conducting pipes, heat pipes, or combinations thereof. The resulting heated fluid, such as water and/or steam, is made available for residential, commercial or other use. If desired, the fluid may be circulated using one or more of driving with an impeller, pumping, siphoning, diffusing, and combinations thereof.

Thus, the system of the embodiments of the invention provides a higher efficiency using a combination of solar thermoelectric energy conversion and mechanical based solar thermal to electrical energy conversion, or solar fluid heating. More generally, a thermoelectric and thermal energy cogeneration method includes steps for receiving and optionally concentrating solar radiation on a solar absorber to heat the absorber, providing thermal energy (i.e., heat) from the absorber to a set of thermoelectric converters, converting a portion of the thermal energy to an electrical energy with the set of thermoelectric converters, providing an unconverted portion of the thermal energy to a displaceable medium, such a water or another fluid, and providing the displaceable medium for subsequent use.

It should be appreciated that the particular implementations shown and described herein are examples of the present invention and are not intended to otherwise limit the scope of the present invention in any way. Further, the techniques are suitable for applications in solar thermoelectric energy and solar thermal energy cogeneration, manufacturing and power plant thermal to electric energy and thermal energy cogeneration, or any other similar applications, particularly applications which presently waste or leave unconverted solar or thermal energy sources.

The thermal efficiency of a solar thermal converter ranges between approximately 50-70%, depending on the operation temperature. The efficiency of a thermoelectric converter is lower. Solar thermoelectric efficiency can be divided into the product of the two terms:

nₑ=nₛₜ(Tₛ,Tₕ)nₜₑ(Tₕ,T_{c}) (3)

The first term reflects the efficiency of solar to thermal energy conversion, converting photons with a characteristic temperature equal to that at the surface of the sun Tₛ, to phonons, or thermal energy, raising the temperature of the hot-side of the solar thermoelectric device to Tₕ. The second term represents the efficiency of the thermoelectric elements generating electrical energy from thermal energy, given a hot-side temperature and cold-side temperature of Tₕ and T_{c}, respectively. As shown in Eq. (1), this latter term depends on the ZT of the thermoelectric materials.

The efficiency ηₛₜ is a function of several heat loss mechanisms, including thermal radiation, convection, and conduction losses from the surfaces of the solar absorber and the thermoelectric elements. The above described solar thermoelectric energy conversion provides optimization of both ηₛₜ and ηₜₑ, and design of a device for cogeneration of thermoelectric energy and thermal energy, or more specifically, the cogeneration of solar thermoelectric energy and solar thermal energy, and addresses the inefficiencies in both conversion processes to improve the solar thermoelectric and solar thermal energy cogeneration.

The temperature difference, ΔT, across the thermoelectric legs needed for power generation is related to the heat flux through the legs, \dot{q}, by the following:

\dot{q}=kΔT/d (4)

where d is the length of thermoelectric legs and k is the thermal conductivity of thermoelectric materials. For a steady-state system, the heat flux \dot{q} is a constant. The average solar flux at the surface of the earth is approximately 1000 W/m². Using this value, and a typical thermoelectric converter constants of k=1 W/mK and d=1 mm result in a temperature difference of ΔT=1° C. A temperature difference this small generates a small amount of electrical energy from the thermoelectric converters. To increase the temperature difference, the heat flux flowing through the thermoelectric device should be increased above the solar flux. In solar thermoelectrics, this can be done by two ways. One way is to optically concentrate the incident solar radiation before it is absorbed and converted into heat, which will be called optical concentration, and the other is concentrate heat via heat conduction, after the solar flux is absorbed. The later will be called thermal concentration. A combination of the two methods can be used depending on applications.

### Thermal Concentrator Configurations

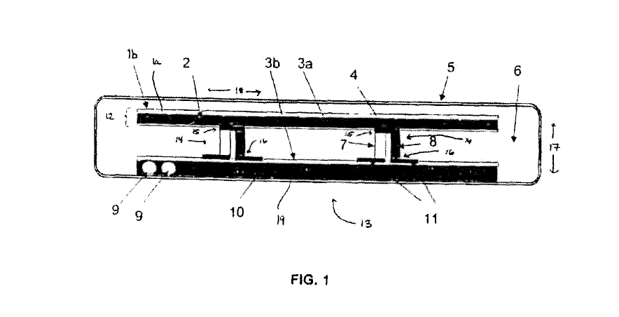

Thermal concentration uses different ratio of solar absorber area to the cross-sectional area of thermoelectric legs. FIG. 1 illustrates the thermoelectric device 13 which will be referred to more generally as solar-electrical generator 13 according to some embodiments of the invention. The generator 13 includes a solar absorber, which will be referred to as a radiation capture structure 12, coupled to one or more pairs of thermoelectric converters 14. The capture structure 12 includes a radiation-absorbing layer 1a that, in turn, includes a front surface 1b that is adapted for exposure to solar radiation, either directly or via a concentrator. Although in this example the front surface 1b is substantially flat, in other examples the layer 1a can be curved. Further, although the radiation-absorbing layer 1a is shown in this example as continuous, in other cases, it can be formed as a plurality of disjoint segments. The solar radiation impinged on the front surface 1b can generate heat in the capture structure 12, which can be transferred to one end 15 of each of the thermoelectric converters 14, as discussed in more detailed below. More specifically, in this example the radiation-absorbing layer 1a can be formed of a material that exhibits high absorption for solar radiation (e.g., wavelengths less than about 1.5, 2, 3, or 4 microns) while exhibiting low emissivity, and hence low absorption (e.g., for wavelengths greater than about 1.5, 2, 3, or 4 microns).

The absorption of the solar radiation causes generation of heat in the absorbing layer 1a, which can be transmitted via a thermally conductive intermediate layer 2 to a thermally conductive back layer 3a. The thermoelectric converters 14 are thermally coupled at an end 15 to the back layer 3a to receive at least a portion of the generated heat. In this manner, the end 15 of the converters (herein also referred to as the high-temperature end) is maintained at an elevated temperature. With the opposed end 16 of the converters exposed to a lower temperature, the thermoelectric converters can generate electrical energy. As discussed in more detail below, the upper radiation absorbing layer 1a exhibits a high lateral thermal conductance (i.e., a high thermal conductance in directions tangent to the front surface 1b) to more effectively transmit the generated heat to the converters.

In some embodiments, such as depicted in FIG. 1, a base or a backing structure 10 (also known as a support structure) is coupled to low-temperature ends 16 of the thermoelectric converters to provide structural support and/or to transfer heat away from the ends 16, i.e., acting as a heat spreader. For instance, the backing structure 10 can be thermally coupled to a heat exchanger in which the fluid provided for use or additional power generation is heated. For instance, as depicted in FIG. 12, a backing structure or base 1220 is in thermal communication with a thermoelectric converter 1210. In other embodiments (e.g., as described below), a heat transfer element may place the backing or support structure in thermal contact with a surrounding evacuated enclosure, thereby acting as a heat sink to help maintain the temperature difference between the high and low temperature ends of the converters.

The fluid conduit 1250 for a solar fluid heating system or a solar thermal power plant is thermally and physically integrated with the thermoelectric device 13. Specifically, the conduit 1250 is coupled to the backing structure 1220 to remove heat therefrom. Vacuum-tight fittings 1260 can be utilized to maintain an evacuated environment around the converter 1210. Conduit 1230 can allow heat transfer from the backing structure 1220 into the conduit 1250 which is schematically drawn as a loop which is provided into a structure 1240 such as a building for hot water generation or to a power plant for steam driven power generation. Other thermal conductive structures coupled to opposed ends 16 of the thermoelectric converters can also be utilized as depicted in FIG. 1.

For the generator (i.e., thermoelectric device) 13 shown in FIG. 1, electrodes 9 are depicted for coupling the generator 13 to an electrical load. Electrically conductive leads 4, 11 are also depicted in FIG. 1, which can provide appropriate electrical coupling within and/or between thermoelectric converters, and can be used to extract electrical energy generated by the converters 14.

The solar-electrical generator 13 depicted in FIG. 1 is adapted to have a flat panel configuration, i.e., the generator 13 has at least one dimensional extent 18, representative of the solar capture surface, greater than at least one other dimensional extent 17 that is not representative of the solar capture surface. Such a configuration can advantageously increase the area available for solar radiation capture while providing sufficient thermal concentration to allow a sufficient temperature difference to be established across the thermoelectric converter to generate substantial electricity. A flat panel configuration can find practical application by providing a low profile device that can be utilized on rooftops or other man-made structures. While the device shown in FIG. 1 is depicted with a flat panel configuration, it is understood that the device of FIG. 1, and others, can be also be configured in non-flat configurations (as described in detail below) while maintaining operability.

In many embodiments, the radiation-absorbing portion of the capture structure can exhibit, at least in portions thereof, a high lateral thermal conductance, e.g., a lateral thermal conductance large enough that the temperature difference across the absorbing surface is small (e.g., less than about 100° C., 50° C., 10° C., 5° C. or 1° C.), to act as an efficient thermal concentrator for transferring heat to the high-temperature ends of the thermoelectric converters. In some embodiments, such as depicted by the substrate layer 2 in FIG. 1, a radiation-capture structure can also exhibit a high thermal conductance in a transverse (e.g., in this case in a direction substantially orthogonal to the absorbing surface 1b) and/or lateral direction to facilitate transfer of heat from the absorbing layer to the converters. For instance, the capture structure can include a radiation-absorbing layer formed of a material with high thermal conductivity, e.g., above about 20 W/m K or in a range of about 20 W/m K to about 400 W/m K. In some embodiments, a thin film can be deposited on a substrate with such thermal conductivity values. High thermal conductance can also be achieved using thicker materials with lower thermal conductivities. Instances of materials that can be used include any combination of metals (e.g., copper-containing, aluminum-containing), ceramics, anisotropic materials such as oriented polymers (e.g., having a sufficient thermal conductance is a desired direction such as in a plane of a layer), and glasses. While the high thermal conductance properties of a capture structure are exemplified by a unitary substrate layer 2 in FIG. 1, it is understood that multiple structures, such as a plurality of layered materials, can also be used to provide the high thermal conductance property desired in some embodiments.

In some embodiments, a capture structure can include a number of components adapted to provide one or more advantageous functions. For instance, the radiation-absorbing layer 1a of the capture structure 12 shown in FIG. 1 can be adapted to selectively absorb solar radiation. For example, the radiation-absorbing layer 1a can be adapted to absorb solar radiation having wavelengths smaller than about 1.5, 2, or 3 microns, or having wavelengths between about 50 nm and about 1.5, 2, or 3 microns, or having wavelengths between about 200 nm and about 1.5, 2, or 3 microns. In terms of the fraction of impinged solar radiation that can be absorbed, the absorbing layer 1a can be adapted to exhibit an absorptivity of solar radiation that can be greater than about 70%, 75%, 80%, 85%, 90%, 95%, 96%, 97%, 98%, or 99%. For example, the radiation absorbing layer 1a can achieve such absorptivity for solar radiation wavelengths in a range of about 50 nm to about 3 microns. In some embodiments, the absorbing layer 1a can comprise one or more coatings that are applied to a substrate 2 to provide the desired selective solar absorptivity properties. One or more selective coatings can be embodied by one or more layers of hetero-materials with different optical indices, i.e., a one-dimensional photonic structure. A selective coating can also be embodied as a grating, surface texture, or other suitable two-dimensional structure. In another example, a selective coating can be embodied by alloying or compositing two or more types of materials, including nano-composites. The substrate 2 can also be part of the selective surface 1b.

In some embodiments, a capture structure's front surface, or other surface adapted to be exposed to solar radiation, can exhibit low emissivity properties over a wavelength range, e.g., at radiation wavelengths greater than about 1.5, 2, 3, or 4 microns. For example, in the above radiation capture structure 12, the front surface 1b can exhibit an emissivity at wavelengths greater than about 3 microns that is less than about 0.3, or less than about 0.15 or less than 0.1, or less than about 0.05, or more preferably less than about 0.01. Such a low emissivity surface can reduce the heat loss from the solar capture structure due to radiative emission. Although such low emissivity can also reduce absorption of solar radiation wavelengths greater than about 1.5, 2, 3, or 4 microns, its effect on absorption is minimal as solar irradiance drops significantly at such wavelengths. In this exemplary embodiment, not only the front surface 1b but also a back surface 3a of the radiation capture structure 12 exhibits a low emissivity. The back surface does not need to be wavelength selective, and its emissivity should be small, in the range of less than 0.5, or less than 0.3, or less than 0.1, or less than about 0.05. The tolerance for high emissivity values depend on the thermal concentration ratio—the ratio of the total solar absorbing surface area to the total cross-sectional area of the thermoelectric legs. The larger is this ratio, the smaller the emissivity should be. The low-emissivity characteristics of the front surface 1b and the back surface 3a do not need to be identical. In some other embodiments, only one of the front and the back surfaces can exhibit low emissivity.

Furthermore, an inner surface 3b of the backing structure 10, which faces the back surface 3a of the radiation capture structure 12, can exhibit low emissivity. The low emissivity can be over all wavelengths, or can be over wavelengths greater than about 1.5, 2, 3, or 4 microns. The low emissivity characteristics of the inner surface 3b can be similar to that of the back surface 3a of the radiation capture structure, or it can be different. The combination of the low emissivity of the back surface 3a of the capture structure 12 and that of the inner surface 3b of the back structure 10 minimizes radiation heat transfer between these two surfaces, and hence facilitates generation of a temperature differential across the thermoelectric converters.

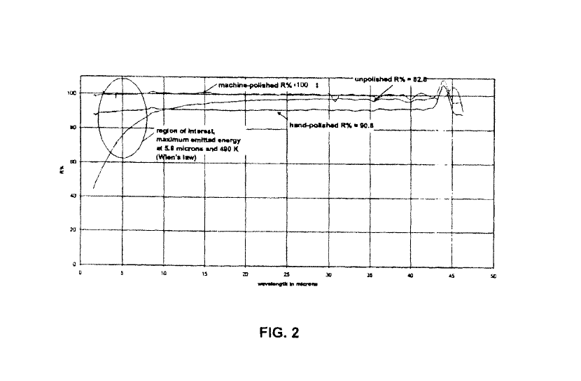

The inner surface 3b can be formed of the same material as the remainder of the backing structure 10, especially when the backing structure is formed of metal (in this case, the electrical isolation among thermoelectric legs should be provided so that electrical current flows in designed sequence, usually in series and sometimes a combination of serial and parallel connections, through all legs). Alternatively, the inner surface 3b can be formed of a different material than the remainder of the backing structure 10, e.g., a different metal having enhanced reflectivity in the infrared. This layer or coating can be a continuous layer, or divided into different regions electrically insulated from each other, or divided into regions electrically coupled together, which can act as interconnects for thermoelectric elements as well. Coatings with high reflectivity, such as gold, can act as low radiative emitters. In general, polished metals can exhibit higher reflectivities, and hence lower emissivities, relative to rough metal surfaces. As shown in FIG. 2, copper surfaces that are polished to better refinements result in surfaces with higher reflectivities, i.e., machine polished copper surfaces have the highest reflectivities, followed by hand polished copper surfaces, and unpolished copper surfaces. The reflectivity measurements of FIG. 2 may have a 3-5% error because the reference aluminum mirror may have reflectivity slightly lower than unity. Such high reflectivities over a wavelength range correspond to low emissivities over that wavelength range, as the sum of reflectivity and a respective emissivity is unity. As well, unoxidized surfaces tend to have lower emissivities relative to oxidized surfaces.

Using any combination of the low emissivity surfaces 1b, 3a, 3b can act to hinder heat transfer away from the capture structure 12, and thus maintain a substantial temperature gradient across the thermoelectric converters 14. When multiple low emissivity surfaces are utilized, the surfaces can have similar properties, or can differ in their emissivity characteristics. In some embodiments, the low emissivity properties of one or more structures can be exhibited over a selected temperature range such as the temperature range that the solar capture surface, or other portions of a capture structure, are subjected to during operation of the solar-electrical generator. For example, the low emissivity properties can be exhibited over a temperature range of about 0° C. to about 1000° C., or about 50° C. to about 500° C., or about 50° C. to about 300° C., or about 100° C. to about 300° C. In some embodiments, the low emissivity properties of any layer(s) can be exhibited over one or more wavelengths of the electromagnetic spectrum. For example, the low emission of any layer(s) can be over wavelengths longer than about 1.5, 2, 3, or 4 microns. In other embodiments, the low emissivity of any layer(s) can be characterized by a surface having a total emissivity value less than about 0.1, less than about 0.05, less than about 0.02, or less than about 0.01 at their working temperature.

In some embodiments, a surface can comprise one or more coatings that are applied thereto in order to provide the desired low emissivity properties, as described earlier. In another instance, low emissivity can be achieved by using multilayered metallodielectric photonic crystals, as described in the publication by Narayanasywamy, A. et al, “Thermal emission control with one-dimensional metallodielectric photonic crystals,” Physical Review B, 70, 125101-1 (2004), which is incorporated herein by reference in its entirety. In some embodiments, other structures can also act as a portion of the low emissivity surface. For instance, with reference to the embodiments exemplified by FIG. 1, the substrate 2 can also be part of the low emissivity surface 1b. For example, a highly reflective metal used as the substrate can be also act as a low emissivity surface in the infrared range, while one or more coatings on top of the metal can be designed to absorb solar radiation.

In some embodiments, an outer surface of the backing structure (e.g., surface 19 in the exemplary solar generator 13) in FIG. 1 can exhibit a high emissivity, e.g., for infrared radiation wavelengths, so as to facilitate radiative cooling. This can be achieved, for example, by depositing an appropriate coating layer on the outer surface of the backing structure.

In the embodiments represented by FIG. 1, among other embodiments herein, a solar-electrical generator can include a portion that is encapsulated (e.g., by a housing) such that the portion is subjected to an isolated environment 6 (e.g., evacuated relative to atmospheric pressure). Preferably, the isolated environment is selected to minimize heat transfer away from the capture structure 12. Accordingly, some embodiments utilize an evacuated environment at a pressure substantially lower than atmospheric pressure. For instance, the evacuated environment can have a pressure less than about 1 mtorr or less than about 10⁻⁶ torr. As depicted in FIG. 1, a housing 5 can encapsulate the entire device 13. At least the top surface of the housing 5 can be substantially transparent to solar radiation, e.g., having high transmissivity and low reflectivity and absorptivity to solar radiation. Potential materials that can be utilized include different types of glasses or translucent plastics. One or more coatings can be applied to one or more sides of the housing walls to impart desired properties (e.g., low reflection losses). In some embodiments, the capture structure 12 can have little to no physical contact with the housing 5 to reduce possible heat transfer away from the capture structure 12. While the embodiments represented by FIG. 1 can utilize a housing 5 that substantially encapsulates the entire solar-electrical generator structure 13, other embodiments can be configured in alternative manners. For example, the solar capture surface 1b can be unencapsulated to receive direct incident solar radiation, while the remainder of the device 13, or the region between the inner surfaces 3a, 3b, can be encapsulated to be in an evacuated environment. It should be noted that the unevacuated environment will generally not be suitable for flat panel type device without any optical concentration, but may be suitable if thermal concentration is combined with optical concentration. The reason is that in flat panel type devices without optical concentration, the absorber surface area is large compared to leg cross-section. If the device is not evacuated, it losses heat to ambient by convection and reduces efficiency. Housings or other structures to contain the evacuated environment can be constructed in any acceptable manner, including within the knowledge of those skilled in the art.

In alternative embodiments, the housing and enclosures discussed herein can be used to enclose an isolated environment, which can be characterized by low heat conductance (e.g., relative to the ambient atmosphere). Accordingly in place of a vacuum, an enclosed environment can include a gas with low thermal conductivity such as an inert gas (e.g., a noble gas such as argon). In another example, insulating materials can be included within an enclosure to limit heat transfer. For instance, the back surface of a capture surface and the inner surface of a backing structure can include a material attached thereto to provide additional insulation beyond the use of low emissivity layer. Thus, embodiments discussed herein which utilize an “evacuated environment” can also be practiced using these alternative environments. Examples of such insulating materials are aerogels and multilayer insulations. However, this is not preferred due to large empty space between absorber and substrate.

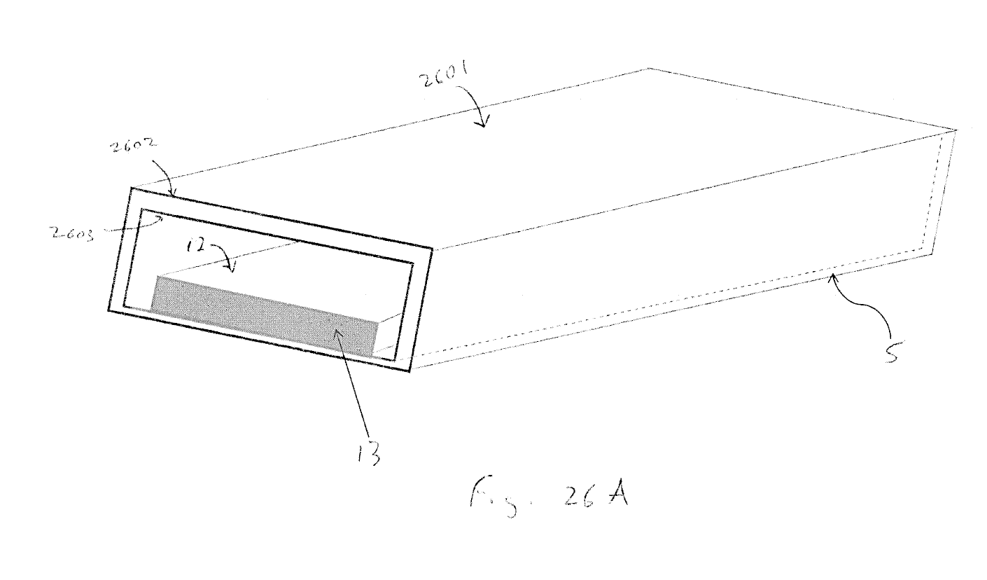

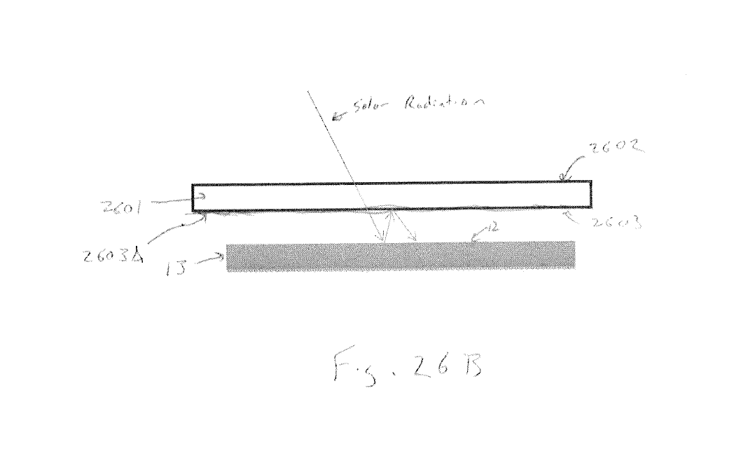

Referring to FIGS. 26A and 26B, in some embodiments the optical properties of the evacuated enclosure 5 about the thermoelectric device may be chosen to enhance the performance of the device 13. As shown, vacuum enclosure 5 includes a clear portion 2601 (e.g., a transparent portion which is made of a material such as glass, quartz or Pyrex). The clear portion 2601 is positioned to receive incident solar radiation which is transmitted through the portion to a hot side of thermoelectric device 13 (e.g., to impinge on a radiation absorber 12 having high absorptivity and low emissivity, as discussed herein). The outer surface 2602 of the clear portion 2601 is highly transmissive to incident solar radiation. The inner surface 2603 of the clear portion 2601 facing the thermoelectric generator has a high reflectivity (i.e. reflectivity of greater than 50%) in a selected wavelength range and which transmits at least 80% of incident solar radiation in the wavelength range of 400 to 700 nm. The selected wavelength range may include wavelengths greater than 700 nm, e.g., greater than 1000 nm. Accordingly, light in the selected wavelength range which is emitted or reflected from the thermoelectric device towards the inner surface 2603 is reflected back on to the hot side of the thermoelectric device. As will be apparent to one skilled in the art, for a suitable choice of wavelength ranges, this configuration will create a “greenhouse” effect limiting the reflective and emissive losses from the thermoelectric device, thereby improving the device efficiency. In some embodiments, the inner surface 2603 is coated with a material layer 2603A which is highly reflective in the selected wavelength range, but exhibits low overall reflectivity and absorptivity to the incident solar radiation impinging on the clear portion 2601. In some embodiments, the coating material may be a thin material layer (e.g., a layer of gold having a thickness of the order of a few nanometers, such as 1-10 nm). In various embodiments, other selective coatings known in the art may be used.

Note that although the embodiments of FIGS. 26A and 26B show a device in a flat panel configuration, a similar technique may be used to create “greenhouse” effect for devices having differing geometries (e.g., curved, tubular, etc.).

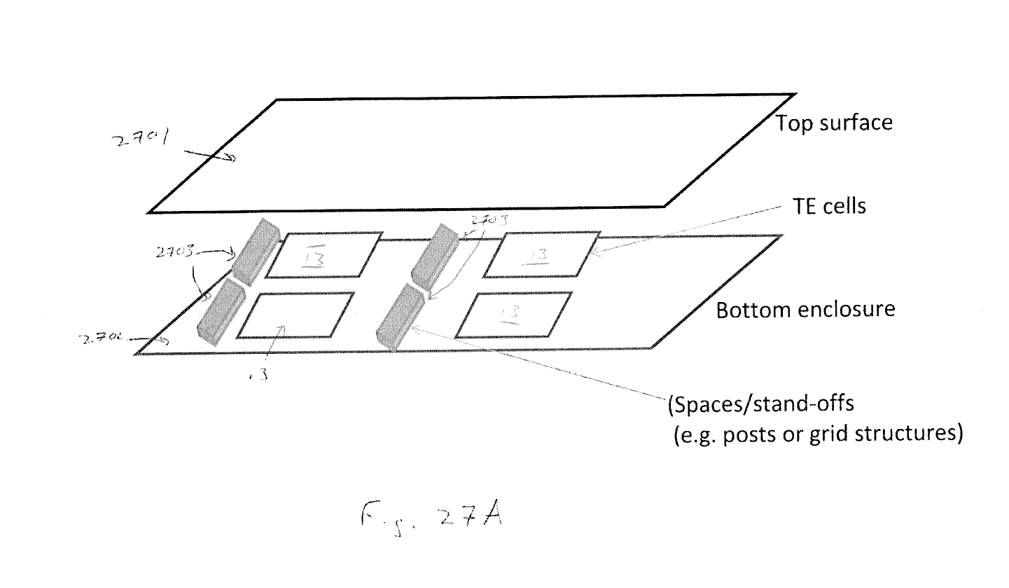

Referring to FIGS. 27A and 27B, in some embodiments, vacuum enclosure 5 may include a top surface 2701 (e.g., made of a transparent material such as glass, quartz, or Pyrex) and a bottom surface 2702 (e.g., made of a transparent or non-transparent material, e.g., metal, glass, Pyrex, etc). Spacers/stand-offs 2703 are positioned between the top surface 2701 and the bottom surface 2702 to provide better mechanical strength. For example the spacers 2703 may contact the top and bottom surfaces to mechanically support the top surface and prevent sag. In some embodiments the spacers 2703 are positioned to enable 10̂-6 torr (or less) vacuums within the enclosure while maintaining the mechanical integrity of the enclosure (e.g. when using standard available glass thicknesses for the top and bottom surfaces 2701 and 2702). In some embodiments, the spacers may be integral with one or both of the top and bottom surfaces 2701 and 2702. As show in FIG. 27A, in some embodiments, the spacers 2703 are located between multiple thermoelectric converter device cells 13. As shown in FIG. 27B, in some embodiments, the spacers 2703 may extend between the top and bottom surfaces through gaps 2704 in one or more thermoelectric converter cells 13. In each case, in typical embodiments, the hot side of the thermoelectric converter device 13 is thermally isolated from the spacers, as shown.

In some embodiments, the spacers may be shaped as thermally insulating rods or as bars (i.e. elongated in at least on direction transverse to the direction from the top surface 2701 and the bottom surface 2702).

Thermoelectric converters, such as the converters 14 depicted in FIG. 1, can generate electricity when a sufficient temperature difference is established across them. In some embodiments, a thermoelectric converter element comprises a p-type thermoelectric leg and a n-type thermoelectric leg, the legs are thermally and electrically coupled at one end, e.g., to form a junction such as a pn junction or p-metal-n junction. The junction can include, or be coupled to, a radiation-capture structure, which can act as a thermal concentrator, consistent with structures discussed herein. A wide variety of materials can be utilized for thermoelectric converters. In general, it can be advantageous to utilize materials having large ZT values (e.g., material with an average ZT value greater than about 0.5, 0.8, 1, 1.2, 1.4, 1.6, 1.8, 2, 3, 4, or 5). Some examples of such materials are described in U.S. Patent Application Publication No. US 2006-0102224 A1, bearing Ser. No. 10/977,363 filed Oct. 29, 2004, and in a U.S. Provisional Patent Application bearing Ser. No. 60/872,242, filed Dec. 1, 2006, entitled “Methods for High-Figure-of-Merit in Nanostructured Thermoelectric Materials;” both of which are hereby incorporated by reference herein in their entirety.

With regard to p-type and n-type materials, such doping of materials can be performed, for example, using techniques known to the skilled artisan. The doped materials can be substantially a single material with certain levels of doping, or can comprise several materials utilized in combination, which are known in some instances as segmented configurations. Thermal electric converters can also utilize cascade thermoelectric generators, where two or more different generators are coupled, each generator operating at in a different temperature range. For instance, each p-n pair can be a stack of p-n pairs, each pair designed to work at a selected temperature. In some instances, segmented configurations and/or cascade configurations are adapted for use over a large temperature range so that appropriate materials are used in the temperature range that they perform best.

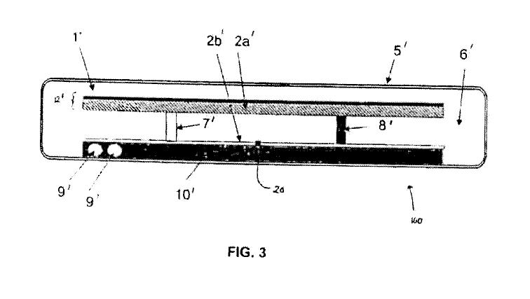

The arrangements of the p-type and n-type elements can vary in any manner that results in an operational solar-electrical generator. For instance, the p-type and n-type elements can be arranged in a pattern that has periodicity or lacks periodicity. FIG. 1 presents one example where p-type and n-type legs 7, 8 are clustered closely together to form a thermoelectric converter 14. Clusters of converter legs, or individual converter legs, can be equally or unequally spaced apart. Pairs of p-type and n-type elements can be used in any number including simply one pair. Another potential configuration can space p-type and n-type elements further apart, as exemplified by the solar-electrical generator 100 shown in FIG. 3. The device 100 is similar in some respects to the solar-electrical generator 13 shown in FIG. 1, having a barrier structure 5′ for providing an evacuated environment 6′ relative to atmospheric pressure, a capture structure 12′ with a capture surface 1′, a backing structure 10′, and electrodes 9′. The capture structure 12′ and the backing structure 10′ can be formed of a metallic material. The metallic material, which can form a layer 2b′, can act as a heat spreader in the backing structure 10′, and in layers 2a′, 2b′ to provide electrical coupling between thermoelectric structures 7′, 8′ on both ends of the structures 7′, 8′. Note that the layer 2b′ on the backing structure 10′ is separated by an insulating segment 20 to prevent short circuiting of the structures 7′, 8′. Accordingly, it is understood that a coating and/or layer as utilized in various embodiments herein can be continuous or discontinuous to provide desired functionality, such as a desired configuration of electrical coupling. Optionally, one or both of the metallic material 2a′, 2b′ surfaces can be polished to have low emissivity, consistent with some embodiments described herein. In the device 100 depicted in FIG. 3, the n-type thermoelectric element 7′ and p-type thermoelectric element 8′ are spaced further apart relative to what is shown in FIG. 1. When a plurality of thermoelectric converter elements are utilized in a solar-thermoelectric generator, p-type and n-type thermoelectric elements can be spaced apart (e.g., evenly) as opposed to being clustered together. For instance, considering heat losses to be due only to radiation, and using a copper material as an absorber, the spacing between legs can be as large as 0.3 m. For example, for use of the generator 13 with a solar water heating system, the legs may be further spaced apart that for use of the generator 13 with a solar thermal power plant. For example, the legs may be spaced apart by 15 to 50 mm, such as about 25 to about 30 mm, for use with a solar water heating system. The legs may be spaced apart by less than 20 mm, such as 1 to 15 mm for use with a solar thermal plant.

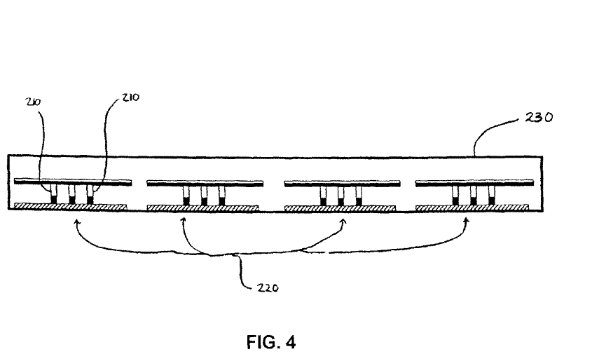

Another potential arrangement of thermoelectric converter elements is depicted in FIG. 4, where multiple thermoelectric converter elements (legs) 210 of a plurality of thermoelectric converters are clustered into groups 220 that are spaced apart. The groups 220 of thermoelectric converter elements 210 are encapsulated by a barrier 230 to enclose the ensemble in an evacuated environment. Such an arrangement can be advantageously utilized when solar radiation is non-uniformly distributed over one or more solar capture surfaces as in embodiments that utilize optical concentrators as described herein. Even if an optical concentrator is not utilized, the arrangement of converter elements could, for example, be configured to follow the path of a sunspot as it travels throughout a day over a capture surface. For the arrangement shown in FIG. 4, the groups are physically separated. It is understood, however, that a device could be embodied as a single entity with groups of converter elements sparsely separated from one another.

The spatial distribution of thermoelectric converter elements can also impact the electrical generation performance of a solar-thermoelectric generator. In some embodiments, the thermoelectric converter elements are spatially arranged such that a minimum temperature difference can be established between a high-temperature portion and a low-temperature portion of a thermoelectric converter element. The minimum temperature difference can be greater than about 40° C., 50° C., 60° C., 70° C., 80° C., 100° C., 150° C., 200° C., 250° C., 280° C., or 300° C. In some cases, such temperature differentials across the thermoelectric converters can be achieved by maintaining the low-temperature ends of the converters at a temperature below about 95° C., 90° C., 80° C., 70° C., 60° C., or preferably below about 50° C., while raising the high-temperature ends of the converters to a temperature no greater than about 350° C., when optical concentration is not employed. For low solar concentration (e.g., a concentration no greater than about 2 to about 4 times incident solar radiation), the temperature can be no greater than about 500° C. Such temperature differentials can assure that the solar-thermoelectric generator operates at a high efficiency. In particular, these temperature specifications can be utilized for a thermoelectric generator that utilizes only incident solar radiation (i.e., unconcentrated radiation) and/or concentrated solar radiation.

Alternatively, or in addition, embodiments can utilize a spatial distribution of thermoelectric converter(s) that provide a limited thermal conductance between their respective ends. While most of heat is designed to go through the thermoelectric converters, meaning that the converter thermal conductance will be more than 50%, even larger than 95% of the total thermal conductance. Otherwise, most heat will be leaking from other conducting paths. However, the converters should be designed with a small thermal conductivity for the legs. Thermal conductance can also be limited by the length of a leg of a thermoelectric converter—longer legs allowing for less thermal conductance. Accordingly, some embodiments limit the ratio of the cross-sectional area to the length of a leg to help decrease thermal conductance by the leg. For example, the ratio of the cross-sectional area of a leg to the leg's length can be in a range from about 0.0001 meters to about 1 meter. Total cross-sectional area reduction from the solar absorber to the set of thermoelectric converters that are on the order of 10:1 and 1000:1 may also be use used.

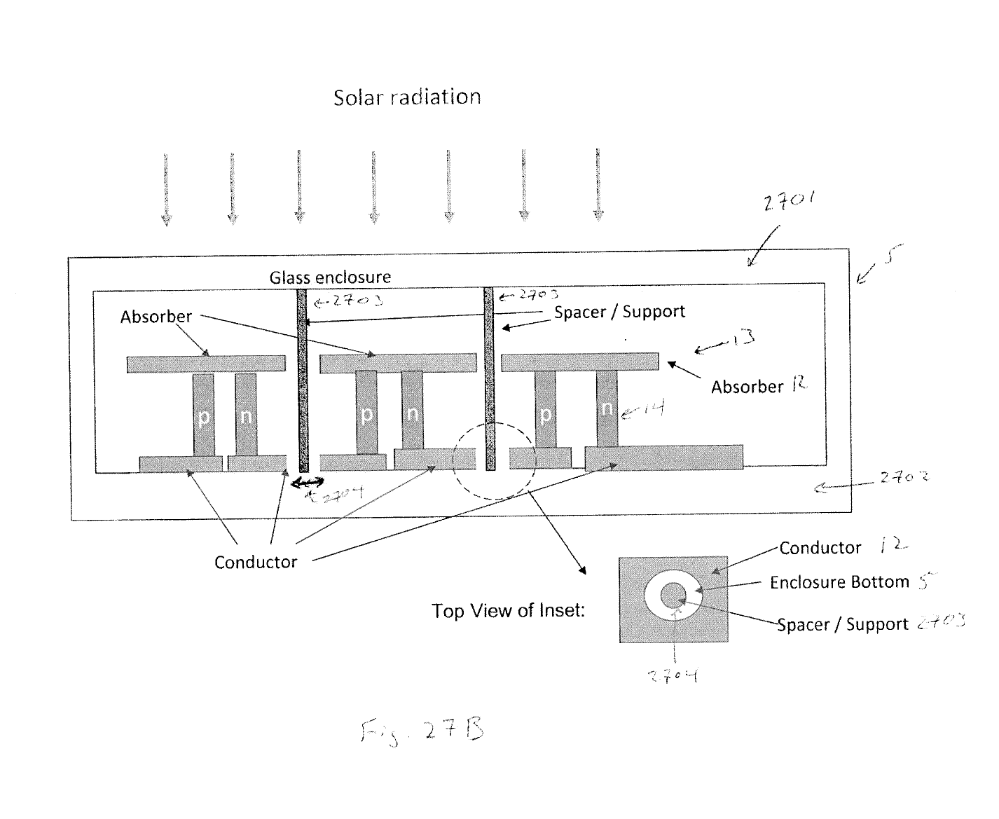

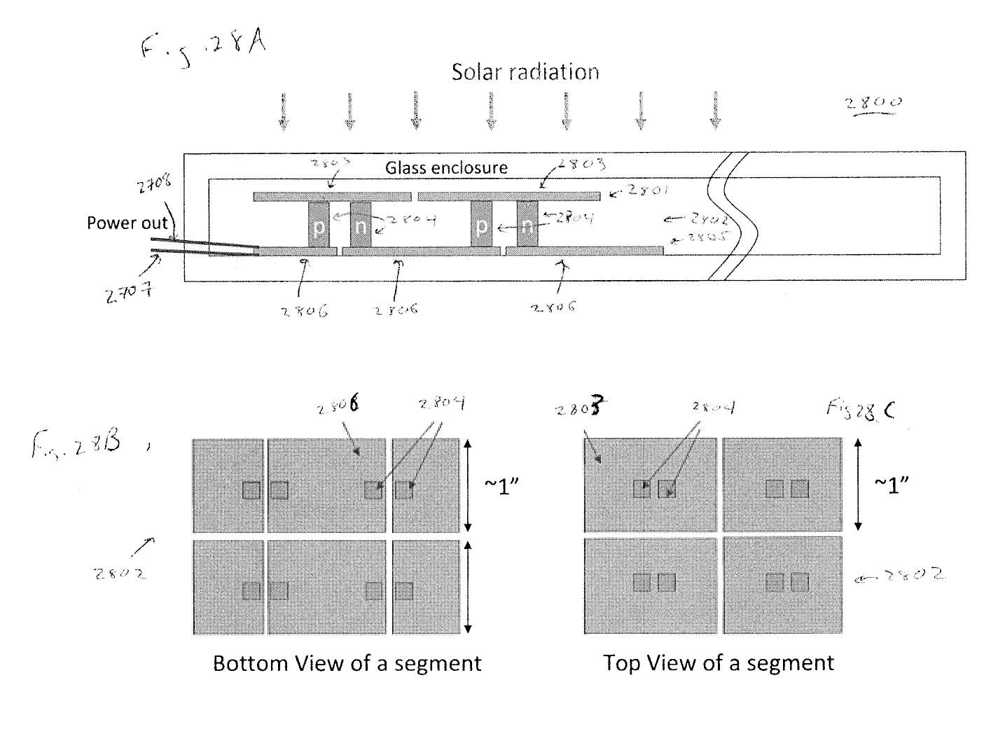

In various embodiments, the placement of the thermoelectric legs may act to spread heat and reduce thermal stress (e.g. shear at the leg/absorber interface). Referring to FIGS. 28A, 28B, and 28C, in the flat panel thermoelectric generator module 2800 shown, the top solar absorber 2801 of the thermoelectric converter 2802 is made up of multiple electrically and thermally isolated sections 2803. Preferably the sections are rectangular. However, other shapes may be used. These absorber rectangles 2803 have a central region surrounded by a peripheral region. For example, the central region may corresponded to the locus of points which are closer to the center of the rectangle than they are to the nearest edge of the rectangle. The top of each pair of thermoelectric legs 2804 (e.g., including a p-type leg and an n-type leg) contacts the central region of an absorber rectangle 2803.

Similarly, the bottom “cold” surface 2805 of the thermoelectric converter 2802 is made up of multiple electrically and thermally isolated sections 2806. Preferably the sections are rectangular. However, other shapes may be used. These bottom rectangles 2806 have a central region surrounded by a peripheral region. For example, the central region may corresponded to the locus of points which are closer to the center of the rectangle than they are to the nearest edge of the rectangle.

The bottom rectangles 2806 are laterally offset from the top absorber rectangles 2803 such that, for each pair of thermoelectric leg 2804, one leg (e.g., a p-type leg) of the pair contacts the peripheral region of only a first bottom rectangle, and the other leg (e.g., an n-type leg) of the pair contacts the peripheral region of only a second bottom rectangle adjacent the first bottom rectangle. As shown, the top and bottom rectangles have a size of about one inch per side. However, in various embodiments, and suitable size such as 0.5 inches to 3 inches may be used.

As shown, this configuration may be repeated for multiple pairs of thermoelectric legs 2804 to produce a series connected electrical and thermal conduction path. For each “link” in the chain, both legs of the pair of thermoelectric legs 2804 contact a top absorber rectangle 2803 in its central region, while the each of the pair contacts the peripheral region of respective adjacent bottom absorber rectangles 2806. Electrically conductive leads 2807 and 2808 are also depicted, which can provide appropriate electrical coupling within and/or between thermoelectric converters, and can be used to extract electrical energy generated by the converters 2804. In some embodiments, leads 2807 and 2808 include a first electrical lead which electrically connects a first section 2806 of the bottom surface 2805 to a load located outside the evacuated enclosure, and a second electrical lead which electrically connects a second section 2806 of the bottom surface 2805 to the load located outside the evacuated enclosure.

In some embodiments, for each pair of thermoelectric legs 2804, the legs extend from the top surface 2801 to the bottom surface 2805 along a length L (e.g., the leg height in the vertical direction in FIG. 28A). The p-type leg contacts the peripheral region of a first bottom rectangle section 2806 at a distance of at least L from a center of the first section, and the n-type leg contacts the peripheral region of a second section 2806 located adjacent the first section at a distance of at least L from a center of the second section. Both legs contact the absorber 2801 at the central region of a rectangular section 2803 at a position having a distance of at least L from a peripheral edge of the section.

Note that although rectangular top and bottom portions are used, any other suitable shapes having a central portion surrounded by a peripheral portion may be used (e.g. squares, circles, ovals, polygons, irregular shapes, or combinations thereof).

In some embodiments, the thermoelectric converters and/or legs of the converters can be distributed in a sparse manner (e.g., relative to the solar capture surface or a backing structure). Sparse distribution of thermoelectric elements can help reduce heat removal via the elements from their high-temperature ends to their low-temperature ends. The arrangements depicted in FIGS. 1 and 3 of thermoelectric converter elements provides some illustrative embodiments of sparsely distributed elements.

In some embodiments where one or more thermoelectric converter elements are sparsely distributed relative to a solar capture surface, the sparseness can be measured by the relative ratio of a solar capture area (herein “capture area”) to a total cross-sectional area associated with converter elements (herein “converter area”). The capture area can be defined by the total amount of area of a selected solar capture surface available for being exposed to solar radiation to generate heat. The converter area can be defined by the total effective cross sectional area of the thermoelectric converter element(s). For instance, with respect to FIG. 1, assuming that all 4 p-type and n-type elements are geometrically similar with uniform cross-sectional areas, the “converter area” can be defined as 4 times the cross-sectional area of a p-type or n-type element, the cross-section of each element being defined by a cross-sectional surface area lying in a putative plane parallel to the capture surface 1b intersecting that element. In general, as the ratio of capture area to converter area increases, the distribution of converter elements becomes more sparse, i.e., there are fewer thermoelectric converter elements relative to the total amount of solar capture surface.

Various embodiments disclosed herein can utilize a range of capture area-to-converter area ratios. In some embodiments, a solar-electrical generator can be characterized by a ratio of capture area to converter area equal or greater than about 100, about 150, 200, about 400, about 500, or about 600, or more. Such embodiments can be advantageous, particularly when utilized with solar-thermoelectric generators having a flat panel configuration that captures solar radiation without the use of a solar concentrator. In some embodiments, a solar-thermoelectric generator can be characterized by a ratio of capture area to converter area greater than about 2, 5, 10, 50, 100, 200, or 300. Such embodiments can be advantageous, particularly when utilized with solar-electrical generators which capture concentrated solar radiation (i.e., a solar concentrator is used to collect and concentrate incident solar radiation onto a solar capture surface). In some embodiments, the incident solar radiation is concentrated onto the absorber with a geometric concentration ratio C, and the ratio of capture area to converter area multiplied by the concentration ratio C is greater than about 10, about 50, about 100, about 200, about 400, about 500, or about 600, or more. In some embodiments, e.g., those featuring non-tracking concentration, the concentration ratio C may be greater than about 1.0, about 2.0, about 3.0, or about 5.0 or more, e.g., in the range of about 1.0 to about 3.0. In embodiments featuring tracking concentrators (i.e. concentrators positioned in response to the movement of the sun), the concentration ration C may be greater than about 10, about 50, about 100, about 1000 or more, e.g., in the range of about 100 to about 1000. Though the embodiments discussed may be advantageous for the particular configurations discussed, it is understood that the scope of such embodiments are not limited to such particular configurations.

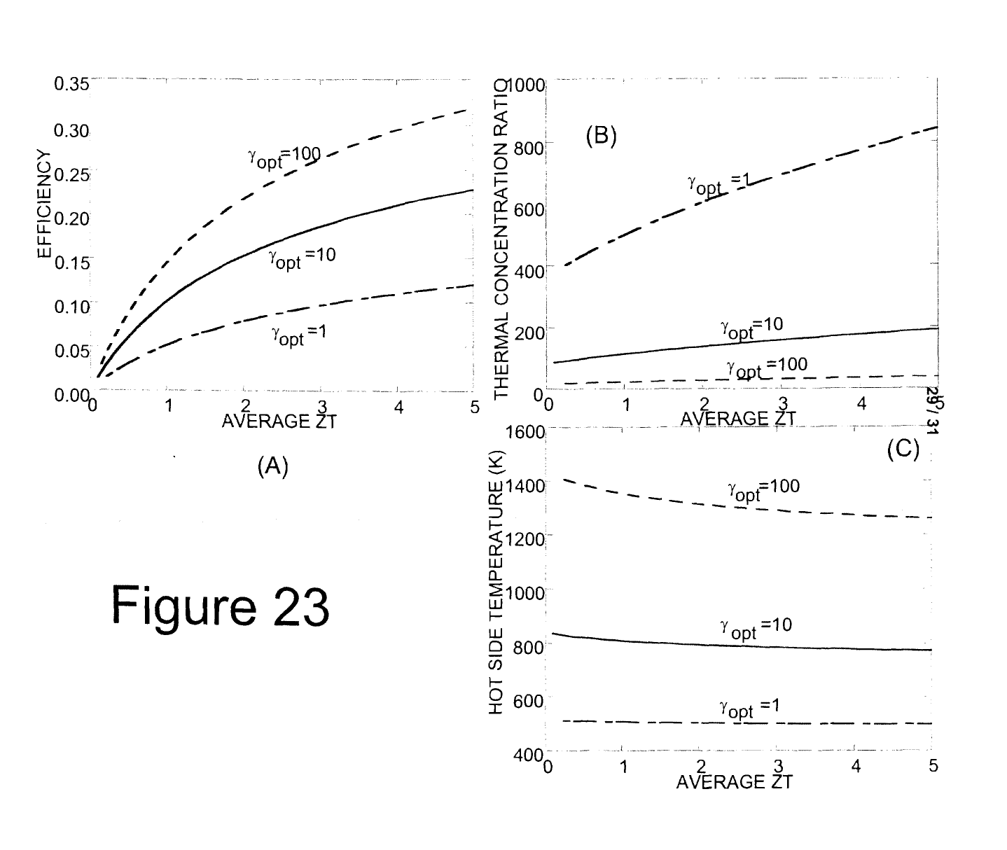

As examples, FIG. 23 shows some exemplary calculations of the efficiency of solar thermoelectric converters. FIG. 23A shows efficiency as a function of nondimensional figure of merit ZT for different optical concentration ratio. Corresponding to each optical concentration ratio, there is also an optimal thermal concentration ratio (the ratio of solar absorbing surface to the total cross-sectional area of the thermoelectric legs). It is understood that these legs may be arranged in different configurations, some are illustrated in FIG. 1 and FIG. 3. Sometimes, a fraction of them can be group together and while other times they can be sparsely and evenly spaced, and yet other times, they can be irregularly spaced. It is understood that in each of these possible configurations, the temperature nonuniformity in the absorber surface is small, preferably be maintained within 1° C., or 5° C., or 10° C., or 50° C., or 100° C. FIG. 23C shows the hot side temperature for the simulated conditions (with the given optical concentration, selective surface properties, etc.). Based on these figures, it is apparent that for each optical concentration ratio, there is usually an optimal thermal concentration ratio (that determines the spacing between legs and cross-sectional area of the legs), and an optimal hot surface temperature. The reason that there is an optimal hot side temperature is as follows: if the hot surface temperature is too high, radiation loss from the surface is too large. If the hot surface temperature is too low, the thermoelectric device efficiency drops. It is understood that these are just exemplary situations, and there are various design flexibilities. For example, optical concentration may be used and yet still maintain the hot side temperature at predetermined temperature, by changing the cross-sectional area of thermoelectric legs.

### Optical Concentrator Configurations

Some embodiments disclosed below utilize solar thermoelectric generator configurations that are adapted for use with one or more optical concentrators. An optical concentrator refers to one or more devices capable of collecting incident solar radiation, and concentrating such solar radiation. The optical concentrator can typically also direct the concentrated solar radiation to a target such as a solar capture surface. In many embodiments in which an optical concentrator is utilized, the concentrator can facilitate generation of a higher temperature differential across the thermoelectric converters, via more efficient heating of their high-temperature ends, which can result in potentially higher electrical output by the converters. An optical concentrator can also be potentially utilized with solar capture structures that have a lower thermal concentration capacity (e.g., smaller solar capture surfaces and/or capture structures that can exhibit larger heat losses) while potentially maintaining the performance of the solar-electrical generator. Though the embodiments described with respect to FIGS. 1, 3, and 4 can be adapted for use where incident solar radiation (i.e., unconcentrated) is utilized, such embodiments can also be utilized in conjunction with an optical concentrator, using any number of the features discussed herein. Similarly, some of the solar-thermoelectric generator designs discussed explicitly with reference to a solar concentrator do not necessarily require such a concentrator.

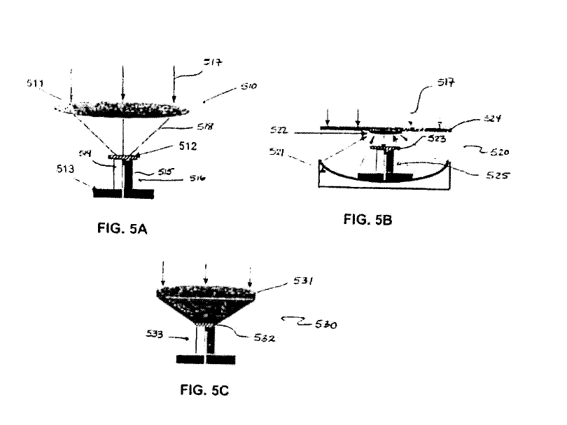

Some embodiments of a solar-thermoelectric generator that includes the use of an optical concentrator are illustrated by the exemplary devices shown in FIGS. 5A-5C. As shown in FIG. 5A, a solar-electrical generator 510 can include an optical concentrator; a radiation-capture structure; a thermoelectric converter element; and a backing structure. For the particular device depicted in FIG. 5A, the optical concentrator is embodied as a transmissive element 511, i.e., an element capable of transmitting solar radiation therethrough. Transmissive elements can be imaging or non-imaging lenses or other transmissive structures capable of concentrating and directing solar radiation. As depicted in FIG. 5A, incident solar radiation 517 can be concentrated by the transmissive element 511 into concentrated solar radiation 518 directed onto a solar capture structure 512 of the radiation-capture structure. In this example, the optical concentrator 511 comprises a convergent optical lens with the radiation capture structure 512 positioned in proximity of its focus to receive the concentrated solar radiation. The concentration of solar radiation can potentially allow the use of a smaller solar capture surface relative to designs that utilize incident solar radiation. Such capture of solar radiation can result in heating of the radiation-capture structure, which can, in turn, heat the thermally coupled ends of the n-type and p-type elements 514, 515 of the thermoelectric converter 516. The backing structure can be configured as a combination electrode/heat spreader 513 structure, which can provide electrical coupling between the n-type and p-type elements 514, 515 and thermal coupling to a heat sink to lower the temperature of the opposed ends of the converter element.

Another embodiment of a solar-electrical generator is depicted in FIG. 5B. For the solar-electrical generator 520, a set of reflective elements 521, 522 act as a solar concentrator. Reflective elements can act to redirect radiation without the radiation passing substantially through the element. Mirrors and structures with other types of reflective coatings can act as a reflective element. For the particular embodiment shown in FIG. 5B, incident solar radiation 517 is directed by structure 524 to mirrored surface 521, which is disposed in this example in proximity of the low-temperature side of the thermoelectric converter 525. The structure 524, which is optionally transparent and/or frame-like, can support the mirror and direct solar radiation downward so that heat spreading can be achieved by a lower substrate. The radiation-reflective element 521 reflects radiation incident thereon to the reflective element 522, which in turn reflects the solar radiation onto radiation capture surface 523 for heating a high-temperature end of the thermoelectric converter 525. In some cases, the reflective element 521 can have a curved shape, e.g., a parabolic, reflective surface that causes the reflective light to be concentrated onto the reflective element 522 (which can be placed, e.g., in proximity of the center of curvature of the reflective element 521). Such concentrated solar radiation is then directed via reflective element 522, which can, in some cases, also provide its own concentration of the solar radiation, onto the radiation capture structure 523.

Another alternative for an optical concentrator is utilized in the embodiment illustrated by FIG. 5C. A solar electrical generator 530 can include a solar collecting transmitter 531 for collecting and concentrating incident solar radiation. The solar collecting transmitter 531 can be closely coupled to a radiation-capture structure 532 (e.g., being in contact or having a very small space or having a thin material in between) to directly channel concentrated solar radiation to the capture structure, potentially resulting in more efficient energy transfer. There can be direct contact between the capture structure 532 and the transmitter 531. Alternatively, a thin thermal insulator (e.g., made of porous glass or a polymeric material) can be lodged between the structures 531, 532. The illustrated embodiment can also be practiced without the need for encapsulating the device in an evacuated environment because of the closer thermal coupling with the thermoelectric converter element 533. As well, when the concentration of solar energy is high (e.g., more than 10 times or 50 times incident solar radiation), convection losses are less important. It is understood, however, that the device could also be utilized in an evacuated environment.

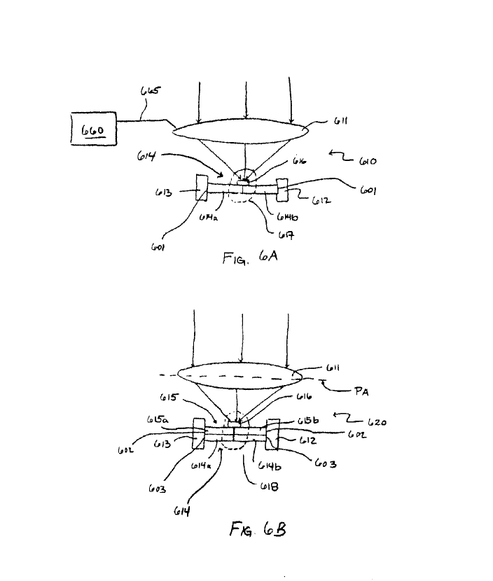

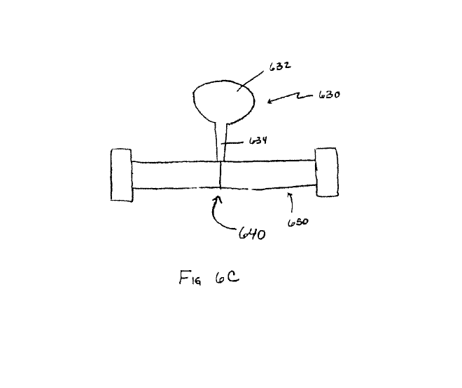

Some embodiments are directed to solar electrical generators in which thermoelectric converters are aligned in alternate configurations relative to those depicted in FIGS. 5A-5C. As shown in FIG. 6A, a thermoelectric converter 614 can be configured so that its n-type and p-type elements (legs) 614a, 614b are aligned along a path such as to have two ends 601. As particularly exemplified in FIG. 6A, ends 601 of the two legs define a substantially linear extent. Here the elements are a p-type leg 614a and a n-type leg 614b, each leg being characterized by an elongated (herein also referred to as axial) direction, though other leg configurations can also be utilized such as curved shapes. In this example, the legs are disposed in a common plane with their axial directions substantially co-aligned. More generally, such legs with axial directions can be disposed in a common plane at an angle relative to one another, where the angle can range from 0 degrees (i.e., co-aligned) to less than about 180 degrees, or about 45 degrees to about 180 degrees, or about 90 degrees to about 180 degrees. In other embodiments, three or more legs can be coupled at varying relative angles. In FIG. 6A, the legs 614a, 614b are aligned in a linear configuration. In particular, the legs 614a, 614b can be horizontally disposed relative to the legs shown in FIGS. 5A-5C, which are vertically-oriented. Such a configuration can provide a number of potential advantages. For instance, the horizontally-oriented legs can provide a more robust mechanical structure vis-à-vis utilizing vertically-oriented legs since the entire device housing for the thermoelectric converter can have a lower profile. The lower profile configuration can aid in the construction of flat-panel configurations for solar-electrical generators and/or providing a smaller volume for encapsulation when such embodiments further utilize an evacuated environment, as discussed herein.

As depicted in FIG. 6A, the elements 614a, 614b share a junction 617 located between the ends 601 of the thermoelectric converter 614. For the embodiment shown here, the junction 617 includes a thermal collector 616 acting as a capture structure, though the junction can also include other types of elements for providing thermal and/or electrical coupling between the elements 614a, 614b. Alternatively, the p-type and n-type elements 614a, 614b can be in physical contact to produce the junction. One or more radiation collectors can be used to collect and capture incident radiation, and direct the concentrated radiation onto the thermoelectric converter so as to heat the junction. For the specific case of FIG. 6A, a lens 611 directs concentrated solar radiation onto the thermal collector 616, which can result in heat generation in the collector 616. As the thermal collector 616 is thermally coupled with the junction 617, it transfers heat generated therein (or at least a portion of such heat) to the junction, thus subjecting the junction 617 to an elevated temperature. A thermal collector 616 can also be a solar radiation absorber, while having low emissivity, as described with respect to other embodiments herein. An example of such a thermal collector material is one or more carbon graphite layers. Further, structures 612, 613 can act as heat spreaders to keep the coupled ends of the elements 614a, 614b at a lower temperature, allowing the thermoelectric converter 614 to generate electricity.

It is understood that a wide variety of geometries can be employed as a capture structure, which can act as a thermal concentrator for directing thermal energy to a junction, as shown in FIGS. 6A and 6B. In some embodiments, it can be advantageous to utilize a capture structure that has a relatively large capture area relative to the junction where thermal energy is directed. FIG. 6C schematically shows one example of a capture structure as a thermally conductive element 630 that can be thermally coupled to the junction 640 of the thermoelectric converter 650 to transfer heat generated therein due to exposure to solar radiation to the junction 640. The thermally conductive element 630 has a mushroom-like shape with a radiation-capture portion 632 that can generate heat in response to exposure to solar radiation. Other shapes can also be utilized. A thermally conductive stem 634 adapted for thermal coupling to the junction 640 provides a thermal path between the radiation-capture portion 632 and the junction 640. Other examples of capture structures with larger capture areas for solar radiation capture relative to the junction areas can also be employed.

While the device 610 shown in FIG. 6A utilizes one thermoelectric converter, it should be understood that other embodiments can utilize a plurality of thermoelectric converters. One example of such a configuration is shown in FIG. 6B, which depicts two thermoelectric converters 614, 615 in a solar-electrical generator 620. Each of the converters 614, 615 can have a p-type leg 614a, 615b and a n-type leg 614b, 615a, where the corresponding p and n-type legs are thermally and electrically coupled. The converters 614, 615 share a common junction 618 that includes a thermal conductor 616. In this embodiment, the p-type and the n-type legs of the two converters are disposed substantially in a common plane. The junction 618 is located between the ends 602, 603 of the converters 615, 614. Optical concentrator 611 directs solar radiation onto the thermal conductor, and hence the junction 618 to heat ends of the converter legs 614a, 614b, 615a, 615b, i.e., the high temperature ends of the converters 614, 615. In this example, the optical concentrator comprises a convergent optical lens which is positioned relative to the thermoelectric converters 615, 614 such that its principal axis PA is substantially parallel to the common plane in which the p-type and n-type thermoelectric legs are disposed. The stacked and horizontal orientation of the converters 614, 615 can act to aid in the design of low-profile, more mechanically-robust solar-electrical generators.

For the various elements depicted in FIGS. 5A, 5B, 5C, 6A, 6B, and 6C such elements can include any of the features or variations associated with such elements as described with respect to various other embodiments of the present invention. Accordingly, the use of one or more low emissivity surfaces, configuring the devices in a flat panel configuration, encapsulating devices or portions thereof in an isolated (e.g., evacuated) environment, and spatially distributing thermoelectric converters can be implemented in any combination, for example.

As well, the embodiments shown in FIGS. 5A, 5B, 5C, 6A, 6B, and 6C can utilize additional components to enhance solar electrical generator performance. For instance, as shown in FIG. 6A, in some embodiments, a solar tracking apparatus 660 can be included to maintain incident solar radiation upon one or more solar concentrator elements 611. Typically, the solar tracking apparatus can include a mechanism 665 for moving one or more elements of a solar concentrator 611 to track the sun's motion to help enhance solar capture. Alternatively, a solar tracking apparatus can also be used in systems without a solar concentrator. In such instances, a thermoelectric module can include a solar capture surface in which the tracking apparatus can move the capture surface to maintain incident solar radiation impingement on the surface. While some of the embodiments discussed herein can be configured to be used without a tracking device, it is understood that solar tracking devices can generally be used in conjunction with any of the embodiments disclosed herein unless explicitly forbidden.

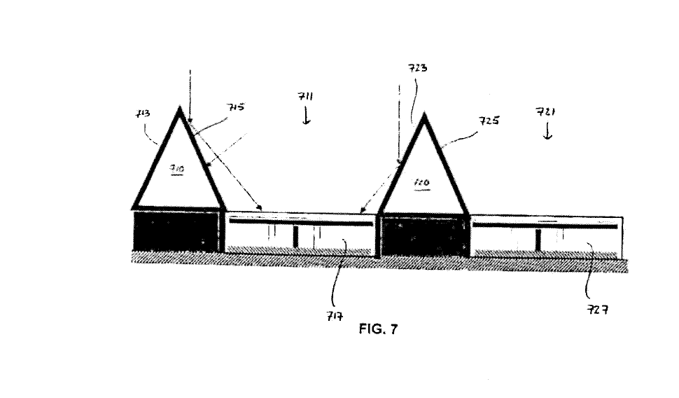

Other embodiments of the invention are directed to solar-electrical generators that utilize a plurality of solar collectors which can concentrate solar radiation in a plurality of regions to provide heating to one or more solar capture structures. Some embodiments utilize a plurality of reflective solar collectors such as exemplified in FIG. 7. As depicted, a plurality of solar collectors 710, 720 are embodied as a set or mirrored surfaces 713, 715, 723, 725 configured to form a plurality of troughs 711, 721. Separate thermoelectric modules 717, 727 can be located in the troughs 711, 721. The mirrored surfaces 713, 715, 723, 725 can reflect solar radiation into the troughs 711, 721 such that the solar radiation impinges upon a capture surface of each of the thermoelectric module 717, 727. This arrangement of the thermoelectric converters and optical concentrators can be extended beyond that shown in the figure. In this case, two slanted reflective surfaces 715, 723 of the solar collectors 710 and 720, which face one another, funnel optical energy onto a radiation-capture surface of the thermoelectric converter 717. Similarly, many of the other thermoelectric converters can receive concentrated solar radiation via reflection of the radiation from two opposed reflective surfaces of two optical concentrators. Such a configuration can be used to provide low level solar radiation concentration (e.g., a solar flux of greater than one and up to about 4 times incident solar radiation). The solar collectors can be adapted such that as the sun and earth move relative to one another, a substantial amount of solar radiation can continually be collected in the troughs. Accordingly, the use of a solar tracker can be avoided in some applications of these embodiments, though in other applications such a tracker may be utilized. In an alternative embodiment, the V-shaped collector of FIG. 7 can be utilized as a secondary collector, where a large solar concentrator with a solar tracking device is used to project solar radiation onto the V-shaped collector. As well, a V-shaped collector can be reduced to be fitted into an isolated environment surrounded by a barrier structure.

The plurality of thermoelectric modules shown in FIG. 7 are embodied as flat panel devices each encapsulated in an evacuated environment. It is understood that other modular configurations, including any of the devices or features of devices disclosed herein, can be utilized instead. In some embodiments, however, the module can be chosen to be consistent with the solar flux that can be generated by such solar collectors (e.g., modules that operate using solar radiation fluxes from 1 to about 4 times incident solar radiation values, which can depend upon collection angles). It is also understood that while FIG. 7 depicts a two-dimensional arrangement, troughs can also be embodied in a three-dimensional arrangement, where each trough is more pit-like, allowing for a three-dimensional distribution of solar-electrical modules.

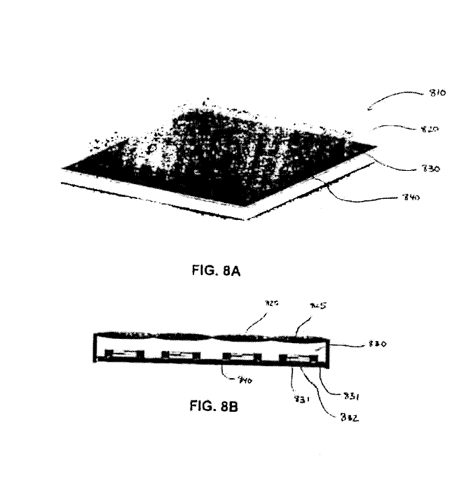

Other embodiments of a solar-electrical generator utilizing a plurality of solar collectors can be configured using different types of solar collectors in different arrangements. For instance, a solar-electrical generator 810 is depicted in a perspective view in FIG. 8A and in a partial cross-sectional view in FIG. 8B. An assembly 820 of solar collectors embodied as a plurality of lens structures 825 serves to capture incident solar radiation. Each of the lens structures 825 can concentrate and direct solar radiation onto a thermoelectric module 830, where for each lens structure 825 a respective module 830 is provided. Each module 830 can be embodied in any number of configurations, including any of the configurations described in the present application. As depicted in FIG. 8B, each module 830 can be configured as a set of thermoelectric converters in a horizontal-orientation, as shown in FIGS. 6A and 6B. Accordingly, the lens structures 825 can be adapted to direct solar radiation onto the corresponding junctions of the modules 830. The modules 830 can be coupled to a backing structure 840, which can optionally be configured as a heat sink to keep ends 831 of the converters at a lower temperature relative to the high temperature ends 832. Like the embodiments exemplified by FIG. 7, the use of the multiple lens structures 825 can direct solar radiation to a specific location, and potentially alleviating the need for a solar tracking device.

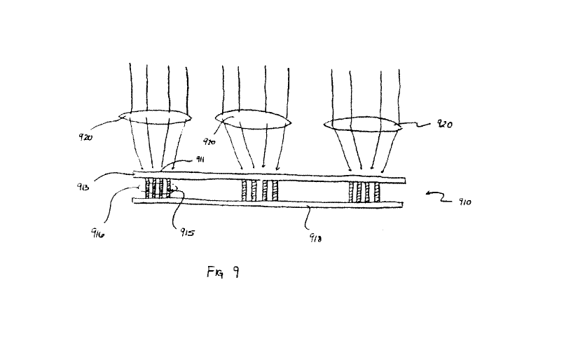

While FIGS. 7 and 8 exemplify some exemplary embodiments in which a plurality of concentrators are used with a plurality of thermoelectric modules, it should be understood that the concentrators can also be configured to be used with a single thermoelectric module. One example of such a configuration is shown in FIG. 9. A set of solar collectors exemplified as lens structures 920 can be used to capture and concentrate incident solar radiation onto a thermoelectric module 910, which can be used to create electricity from the concentrated solar radiation. Such a module can include any number of the features described with respect to the module depicted in FIG. 1 (e.g., low emissivity surfaces, flat panel configuration, and/or evacuated environment). For the particular configuration depicted in FIG. 9, the module 910 can include groupings 916 of p-type legs and n-type legs 915 that are spaced apart relative to a capture structure 913. Each lens structure 920 can be adapted to direct concentrated solar radiation onto a portion 911 of the capture structure solar collection surface, where the portion can correspond with the proximate location of a grouping 916 of legs 915. It is understood that variations in the design of the system depicted in FIG. 9 (as is the case for FIGS. 7 and 8) can be employed consistent with embodiments of the present invention. For example, a different configuration of solar collectors (e.g., using properly configured reflective surfaces) could be employed instead of the lens structures. One optical concentrator can used with respect to the module shown in FIG. 9 as well. In such an instance, the focus/concentrated light spot can move following the sun if the device does not utilize tracking. One thermoelectric unit in the set can produce higher efficiency due to reduced size, and hence a lower radiation loss.

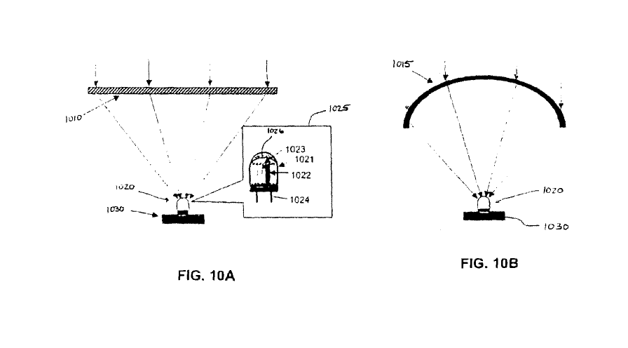

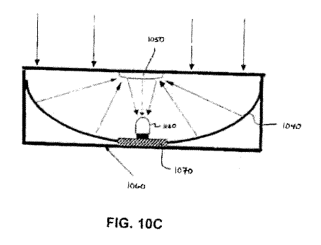

While the embodiments depicted in FIGS. 7-9 have shown the use of a variety of thermoelectric module configurations with solar concentrators, other module designs are also possible. One alternative module design and its use is depicted in FIGS. 10A and 10B. As shown in FIG. 10A, a solar collector 1010, which can be embodied as a Fresnel lens or some other type of diffractive element, is used to focus concentrated solar radiation onto a thermoelectric module 1020, which can be thermally coupled to a heat spreader 1030 (or more generically coupled to a support structure). Other types of potential solar collectors include using one or more lens elements, reflective elements, and/or refractive elements. In some embodiments, the thermoelectric module 1020 can be removably coupled (e.g., mechanically, thermally, and/or electrically) to the heat spreader 1030. Accordingly, the module 1020 can be replaced easily into the heat spreader for enhanced maintenance of such a system.

A more detailed view of the thermoelectric module 1020 is provided in the blow up box 1025 in FIG. 10A. The module 1020 can include a barrier structure 1021 (in this case a bulb-like structure) which encloses the module 1020 in an isolated environment. The isolated environment can be an evacuated environment relative to atmospheric pressure, or can comprise an atmosphere which has low thermal conductance relative to the ambient atmosphere. Examples can include the use of gases having low heat capacities such as an inert gas. Thermally insulating materials can also be incorporated within the barrier structure 1021 to reduce heat loss from high-temperature ends of the thermoelectric module. The barrier can be adapted to be at least partially transmissive to solar radiation, where the barrier can include any number of features as described for the encapsulation with respect to FIG. 1. For the particular configuration shown in FIG. 10A, the barrier structure 1021 forms at least part of a bulb-like enclosure; other geometrical configurations are also contemplated. The barrier structure 1021 can optionally include a lens structure 1026, which can further direct and/or concentrate solar radiation impinging on the barrier structure 1021. Within the enclosure, a radiation-capture structure 1023 can be coupled to the legs 1022 of a thermoelectric converter. Solar radiation impinging on the barrier structure 1021 can be directed onto the capture structure to generate heat, and keep one end of the legs 1022 at a relatively high temperature. Electricity generated by the legs 1022 of the converter can be coupled to an electrical load via electrodes 1024.

Thermoelectric modules that utilize the barrier structure exemplified in FIG. 10A can afford a number of advantages. The module can be configured compactly, having a reduced volume (e.g., relative to the volume of a larger flat panel configuration) to facilitate ease of maintaining an evacuated environment. The use of a solar concentrator (e.g., solar concentrators that provide a high degree of concentration such as greater than about ten times incident solar radiation) can allow the use of smaller capture structures for thermal concentration, which enables the use of smaller volumes. As mentioned previously, such compact structures can also be modular in nature, allowing ease of replacement of such modules. This aspect can be particularly advantageous in configurations that include a multiplicity of modules. For instance, the system depicted in FIGS. 8A and 8B can utilize the encapsulated module 1020 of FIG. 10A instead of the module 830. This can provide for ease of maintenance if one module becomes broken. It is understood, however, that the module 830 of FIGS. 8A and 8B can also be contained in a replaceable modular configuration that is encapsulated.

A variety of other configurations are contemplated beyond what is shown in FIG. 10A, including those modifications apparent to one skilled in the art. For instance, the Fresnel lens concentrator can be configured as a flat structure 1010 as depicted in FIG. 10A, or as a structure having a curve 1015 as shown in FIG. 10B. As well, other types of optical concentrators beyond Fresnel lenses can be used, such as other types of diffractive elements. As shown in FIG. 10C, a solar-electrical device 1060 can utilize two reflectors 1040, 1050 as a solar collector direct solar radiation to the thermoelectric module 1020, akin to what is shown as described with respect to FIG. 5B. The heat spreader 1070 can be thermally coupled to the environment to provide a heat sink. As well, encapsulated designs can utilize a solar tracker, as discussed herein, to maintain solar radiation on a portion of the encapsulated structure. Such designs can aid in maintaining a particular level of concentrated solar radiation on the encapsulated structure (e.g., at least 10 time incident solar radiation). All these variations, and others, are within the scope of the present disclosure.

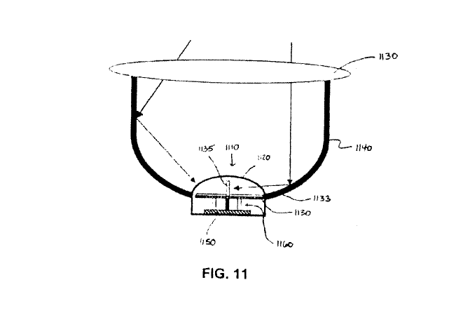

Another modular configuration for use with the various solar-electrical embodiments discussed herein is depicted in FIG. 11. A solar concentrator for use in directing and concentrating solar radiation can include a reflective element 1140 (e.g., a parabolic mirror). Another optical element 1130 (e.g., a convergent lens) can also be used to direct incident solar radiation toward the reflective element 1140. The reflective element 1140 can, in turn, concentrate and direct the solar radiation incident onto the thermoelectric module 1110. The module 1110, which can optionally be encapsulated in an enclosure 1120 to provide an evacuated environment relative to atmospheric pressure, can include a radiation-capture structure 1130, which can include one or more surfaces for absorbing solar radiation. The capture structure can generate heat upon exposure to solar radiation. The capture structure can include one or more protruding elements 1135 that can be adapted to receive some of the solar radiation reflected by the reflective element 1140, and can further be configured to generate heat by absorbing at least a portion of the solar radiation spectrum. For example, as depicted in FIG. 11, the protruding element 1135 is substantially perpendicular to the flat surface 1133 of the capture structure 1130. Accordingly, the parabolic mirror need not be configured to direct light only to a flat surface, but can also direct light on the protruding surfaces. Such a design can be advantageous since it can provide flexibility on the requirements on solar collector designs, and can increase the heat generating capacity of a capture structure. A protruding element can allow a capture structure to absorb solar radiation from a multiplicity of angle and directions (e.g., including directions that cannot be captured by a single flat surface). One or more thermoelectric converters 1160 can be coupled to the capture structure 1130, with one end of the converter thermally coupled to the capture structure and another end coupled to a heat spreader 1150. The protruding element can be composed and designed in accord with any of the capture structures disclosed in the present application (e.g., a metal or other material with high selective solar absorbance and/or low emissivity to infrared light). As well, the design of a module with a protruding element can be in a removably couplable module as discussed with respect to FIGS. 10A-10C.

The following example is provided to illustrate some embodiments of the invention. The example is not intended to limit the scope of any particular embodiment(s) utilized, and is not intended to necessarily indicate an optimal performance of a thermoelectric generator according to the teachings of the invention.

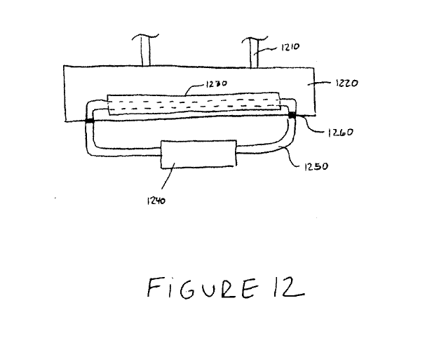

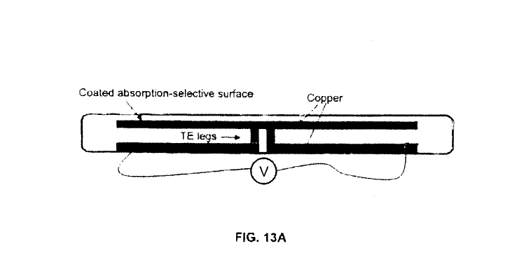

FIG. 13A illustrates a prototype of a thermoelectric generator and its performance. FIG. 13A is a schematic of the prototype. The generator made of one pair of p-type and n-type commercially available thermoelectric elements. A thickness of ˜1 mm is utilized in our thermoelectric elements. The thickness of the legs can be from 20 microns and up to 5 mm. A selective absorber made of copper is attached to the top of the legs and also serves as an electrical interconnect. The experimental apparatus was tested inside a vacuum chamber. The power output from the pair of legs under ˜1000 W/m² illumination is shown in FIG. 13B, and the efficiency is shown in FIG. 13C. This prototype did not use parallel plates and did not attempt to increase the reflectivity of the backside of the absorber. By taking these measures, among others which are disclosed in the present application, higher efficiencies can potentially be achieved.

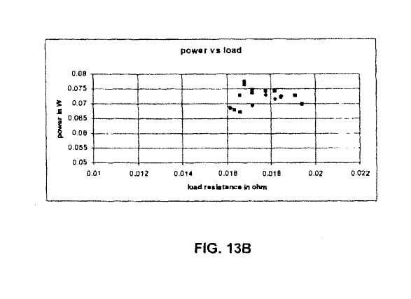

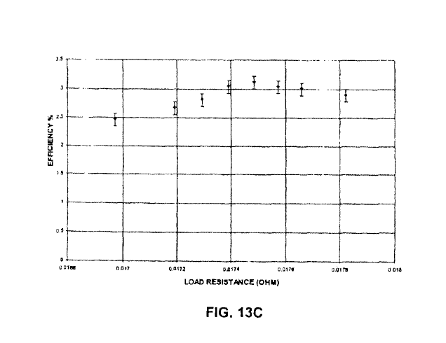

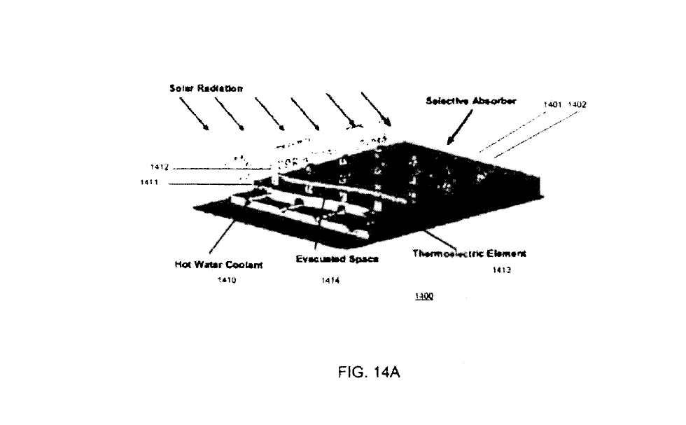

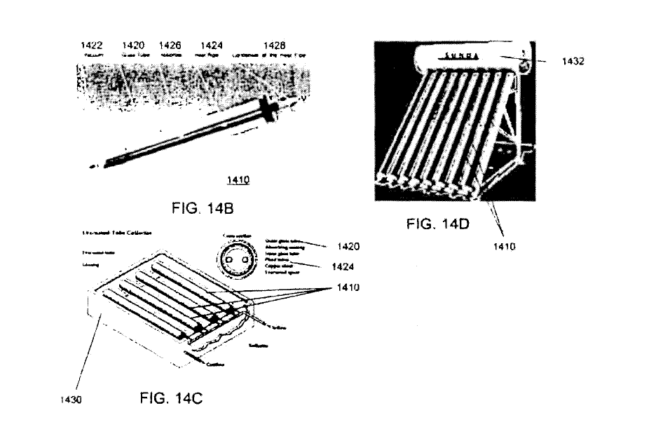

FIG. 14A illustrates an embodiment of a solar thermal-thermoelectric (STTE) converter 1400 used in the cogeneration of solar thermoelectric energy and hot water heat in accordance with the present invention. Solar radiation is incident onto a selective surface 1401 of a solar absorber 1402, such as, for example, the radiation capture structure 12 shown in FIG. 1, of the STTE converter. The selective surface absorbs the solar radiation but emits little thermal radiation, allowing the solar absorber to heat up to designed temperature, for example, in the range of 150-300° C., or 300-500° C. Thermoelectric converters 1413 separate the solar absorber 1402 at a hot-side 1412 of the STTE converter from the set of conduits 1410, such as pipes or plates carrying water, or another fluid, at a cold-side 1411 of the STTE converter. The converters 1413 are located inside the evacuated space 1414.

FIGS. 14B, 14C and 14D illustrate exemplary fluid conduits that may be used in the STTE converter system 1400. Specifically, these figures illustrate conduits used in prior art solar thermal systems that lack the thermoelectric converters, but which can be used together with the thermoelectric devices, such that the conduits are not just fluid carrying tubes, but contain thermoelectric devices that should be on top of them. Specifically, the absorber material in the prior art conduits should be replaced by a thermoelectric device, such as the device shown in FIG. 1, where the bottom substrate of the thermoelectric device is thermally linked to the heat carrying fluid conduits. It should also be noted that the conduits and the external glass tubes do not have to be circular and may have other shapes. For example, FIG. 14B illustrates an evacuated conduit 1410 which contains a glass tube housing 1420 enclosing a vacuum chamber 1422, a fluid carrying heat pipe 1424 coated with an optional thermal absorber 1426 (which may be omitted in system 1400) located in chamber 1422 and an optional condenser 1428 at the end of the heat pipe FIG. 14C illustrates an example of an array of conduits 1410 in a housing 1430 containing fluid carrying inner tubes or pipes 1424 inside outer glass tube housings 1420. The tubes 1420, 1420 do not have to be made of glass, since they do not receive solar radiation, but may be made of a thermally conductive material, such as a metal. FIG. 14D illustrates a plurality of conduits 1410 which are positioned at an angle with respect to the ground and which are connected to a fluid tank 1432 located above the conduits.

Heat absorbed by the solar absorber is conducted to the set of thermoelectric converters 1413, concentrating the heat stored in the solar absorber 1402 at the set of thermoelectric converters 1413, where the conversion from thermal to electrical energy takes place. Heat conducted through the thermoelectric converters themselves from the hot-side 1412 of the STTE converter to the cold-side 1411 of the STTE converter approaches heat transfer levels associated with conventional solar thermal conversion for hot water heating systems. The benefit in the inventive STTE converter over standard solar thermal converters is an additional solar thermoelectric energy conversion, which generates electrical power at less than $1-$2/Watt at current energy prices.

By comparison, current PV cell prices generate electrical power at approximately $4/Watt to $7/Watt current prices, depending on installation costs. In the preferred embodiment of the present invention, the STTE converter installation costs are combined with the installation cost of the hot water systems, reducing the installation cost.

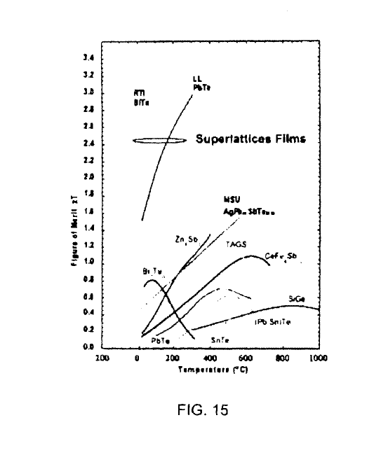

The combination of thermal energy concentration and solar energy concentration can be used to adjust a solar thermoelectric converter to function at an peak operating temperature that leads to maximum efficiency. The peak operating temperature depends on the optical concentration used and the materials available. FIGS. 23A-C illustrate examples of how the peak operational temperature may change with optical concentration ratio, while FIG. 15 presents a series of plots of ZT as a function of temperature for several well-known and currently investigated thermoelectric converter materials. All these materials, and other materials currently available and under development, can be used for solar cogeneration systems. Examples of these materials are: SiGe (e.g., Si₈₀Ge₂₀), Bi₂Te₃:Bi₂Te₃₋ₓSeₓ (n-type)/BiₓSe₂₋ₓTe₃ (p-type), and PbTe, skutterudites (CoSb₃), Zn₃Sb₄, and AgPbₘSbTe₂₊ₘ, and Bi₂Te₃/Sb₂Te₃ quantum dot superlattices (QDSLs), PbTe/PbSeTe QDSLs, and PbAgTe. In general, combination of different materials, in the form of segmented legs (a thermoelectric leg with different materials distributed along the leg) or cascade devices (a stack of devices each operating in certain temperature range) can be used in the solar thermal co-generation systems.

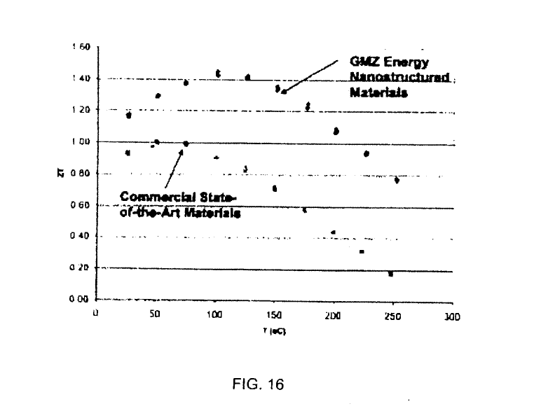

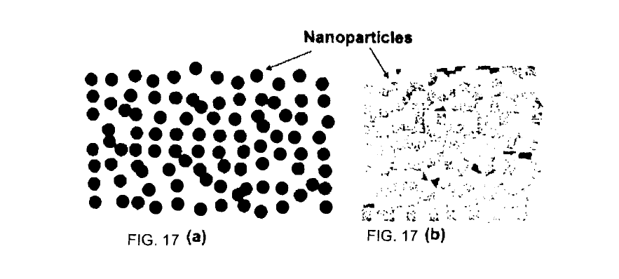

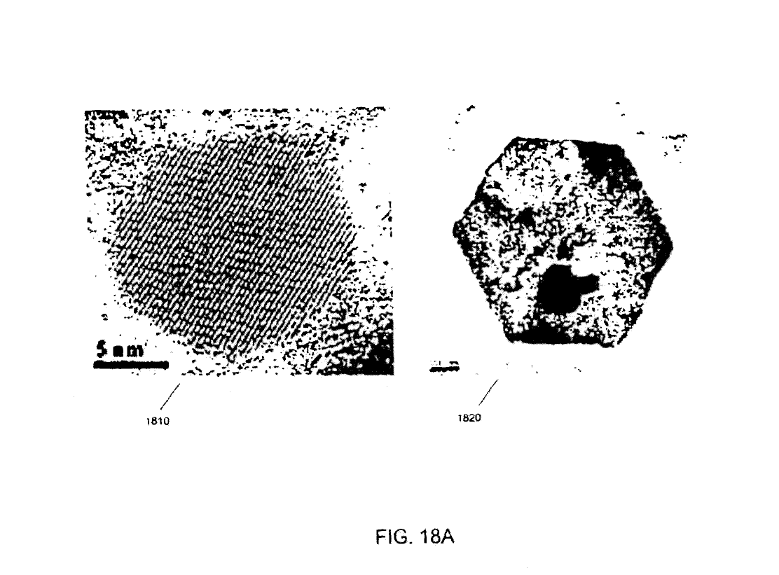

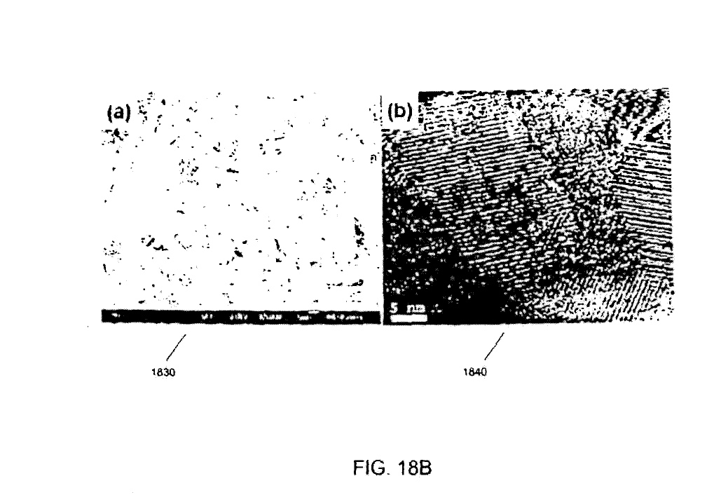

In recent years, significant progresses have been made in improving ZT of thermoelectric materials. Most commercial thermoelectric devices are built on Bi₂Te₃ and its alloys with a peak ZT about 1. Some progress in ZT is summarized in FIG. 15. Among such progress is the discovery of new materials, such as skutterudites, and nanostructuring of existing materials, such as superlattices. The nanostructred bulk materials which comprise compacted semiconductor nanoparticles are particularly attractive since the materials are in a form that is compatible with solar thermal co-generation schemes and yet are with a higher ZT and economical. FIG. 16 shows compares the ZT of nanostructured bulk Bi2Te3 alloy with that of commercial Bi2Te3 alloys, demonstrating improved ZT. Such nanostructured bulk materials can be compacted from nanoparticles of the same material (such as silicon, SiGe, Bi₂Te₃, Sb₂Te₃, etc.) shown in FIG. 17A, or compacted nanoparticles of different materials, in which the nanoparticles of one material form a host matrix and the nanoparticles of the second material form inclusions in the host matrix, as shown in FIG. 17B. The compaction may be conducted using hot pressing or direct current induced hot pressing. FIG. 18A presents TEM images of Bi₂Te₃ 1810 and Bi₂Se₃ 1820 nanoparticles synthesized by wet chemistry and FIG. 18B presents high-resolution SEM 1830 and TEM 1840 images of Bi₂Te₃ based alloy compacted nanopowders. The TEM image, 1840, provides evidence of a nanodomain structure for Bi₂Te₃ based alloy nanopowders.

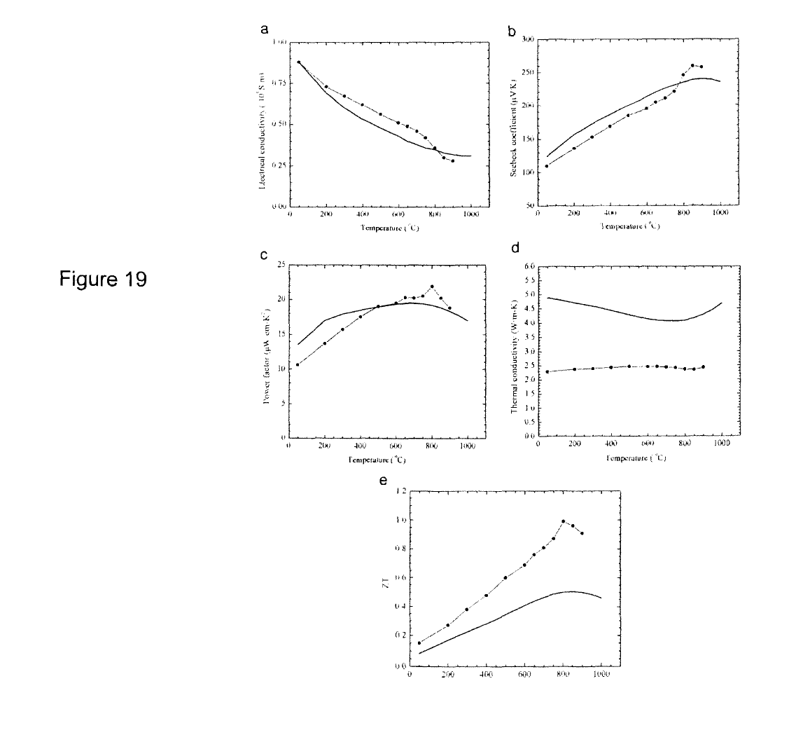

FIGS. 19(a)-(e) show properties of nanostructured bulk SiGe as another example. Nanostructured SiGe alloy particles are prepared by mechanical alloying using a ball mill technique. In this approach, boron (B) powder (99.99%, Aldrich) is added to silicon (Si) (99.99%, Alfa Aesar) and germanium (Ge) (99.99%, Alfa Aesar) chunks in the milling jar. They are then milled for a certain time to get the desired alloyed nanopowders having a mean size of about 20 to 200 nm. The mechanically prepared nanopowders are then pressed at different temperatures by using a dc hot press method to compact the nanopowders in graphite dies. The compacted nanostructured Si₈₀Ge₂₀ materials consist of polycrystalline grains of sizes ranging from 5 to 50 nm with random orientations, such as 5 to 20 nm In FIGS. 19A-E, dots represent nanostructured SiGe, and solid lines represent p-type SiGe used in past NASA flights as radio-isotope power generators (RTG). FIGS. 19A-C show that the electrical transport properties of nanostructured SiGe can be maintained, with a power factor comparable to that of RTG samples. However, the thermal conductivity of the nanostructured bulk samples is much lower than that of the RTG sample (FIG. 19D) over the whole temperature range up to 900° C., which led to a peak ZT of about 1 in nanostructured bulk samples Si₈₀Ge₂₀ (FIG. 19D). Such a peak ZT value is about a 100% improvement over that of the p-type RTG SiGe alloy currently used in space missions, and 60% over that of the reported record. The significant reduction of the thermal conductivity in the nanostructured samples is mainly due to the increased phonon scattering at the numerous interfaces of the random nanostructures.

Solar radiation is incident onto the selective surface of the solar absorber of the STTE converter. The selective surface absorbs the solar radiation but emits little thermal radiation, allowing the solar absorber to store heat. Thermoelectric converter elements separate the solar absorber at a hot-side of the STTE converter elements from the set of conduits, such as pipes carrying water, or another fluid, such as oil or melton salt, at a cold side of the STTE converter elements.

The efficiency of STTE converter depends on the properties of the selective surfaces 1401 of the solar absorber 1402. Solar radiation peaks at a wavelength of about 0.5 μm. Wavelengths longer than 4 μm account for less than 1% of total solar radiation. Less than 0.2% of the radiation emitted from a surface at 300 K has wavelengths shorter than 4 μm. An ideal selective surface of the solar absorber is designed to absorb 100% of the solar radiation and emit 0% of the stored thermal radiation. That is, an ideal selective surface of the solar absorber has an emissivity of 1.0 for wavelengths less than 4 μm and an emissivity of 0.0 for wavelengths greater than 4 μm.

Some commercial selective absorbers have characteristics close to the aforementioned requirements. For example, ALANOD Sunselect GmbH & Co. KG provides materials with absorptivity of 0.95 for solar incident radiation and 0.05 for thermal emission from the selective surface, with a transition wavelength around 2 μm. Low emissivity between a set of inner surfaces separated by the thermoelectric converters 1413 is important to reduce thermal radiation from leaking from the hot-side 1412 of the set of thermoelectric converters 1413 to the cold-side 1411 of the thermoelectric converters.

The solar absorber should be connected to a set of electrical contacts for the set of thermoelectric converters 1413. Solar absorbers patterned on copper foil substrates provide both high lateral thermal conductivity and low resistance electrical contacts to the set of thermoelectric converters. An additional thin layer of gold, or another thin metallic layer, coating the selective surface of the solar absorber and the surface facing the cold-side of the set of thermoelectric converters 1413 can reduce the selective surface emissivity to 0.02 for thermal radiation energies. Additionally, a volume 1414, shown in FIG. 14A, between the hot-side 1412 and the cold-side 1411 is evacuated to limit heat loss from the hot-side to the cold-side by means of convection.

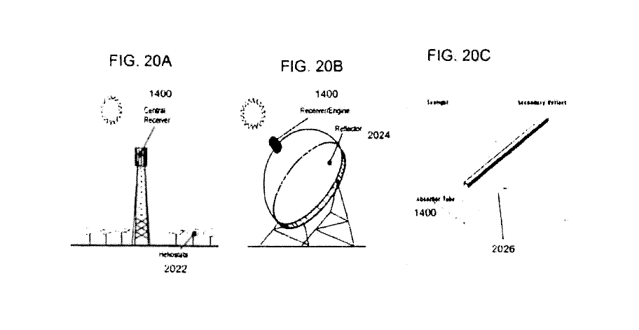

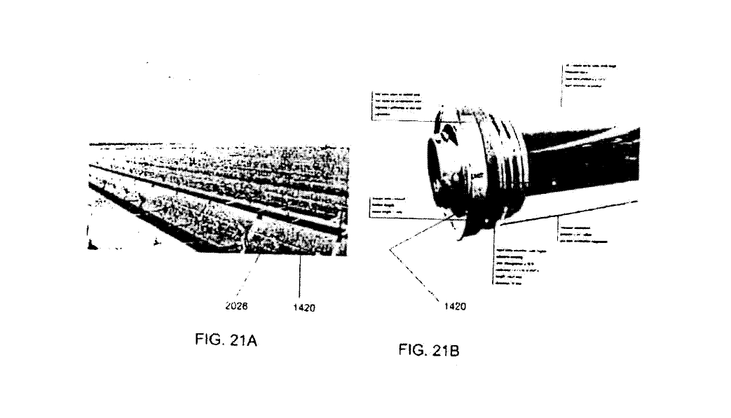

FIGS. 20A-20C illustrate various two dimensional (2D) 2010 and three dimensional (3D) 2020 solar energy flux concentrators for the cogeneration of solar thermoelectric energy and fluids used in current or future thermal power plant in accordance with a preferred embodiment of the present invention. In one embodiment, the thermoelectric device is physically and thermally integrated with a solar thermal plant which heats a fluid and uses the heated fluid to generate electricity. The thermoelectric converters are used as a topping cycle in combination with 2D and 3D solar thermal plants, driving Rankine or Stirling heat engines. 2D and 3D solar concentrators such as heliostats 2022 shown in FIG. 20A, dishes 2024 shown in FIG. 20B, and troughs 2026 shown in FIG. 20C may be used. Solar radiation is focused onto a selective or a non-selective surface, depending on the solar concentrator level. The solar absorbing surface is thermally coupled to a thermoelectric device, and heat rejected at the cold side is used to heat up the fluids used in a thermal power plant to drive mechanical power generation engines (Rankine and Stirling).

The solar absorber 1402 shown in FIG. 14A is coupled thermally to the hot-side 1412 of the thermoelectric converters 1413. The cold-side 1411 of the thermoelectric converters 1413 exchanges heat with a fluid in conduits 1410 that drives Rankine or Stirling heat engines, or any pump based on a thermal-mechanical heat cycle. In a preferred embodiment, heat engines are driven by the fluid directly. In a Stirling converter, the fluid may comprise a gas (if any liquid is present, then it is used only for coupling heat to the Stirling engine which contains a gas inside of it). In the Stirling converter, the solar radiation is focused onto an absorber, and heat generated is transferred to heat up gas inside a Stirling engine. The above described thermoelectric device can be used as a topping cycle for such Stirling engine. Heat rejected in the cold side of thermoelectric device can be provided directly into the gas rather than being provided to the gas via a different fluid. In another preferred embodiment, a heat exchanger (not shown) exchanges heat with a medium external to the thermoelectric converter system and the medium, such as a liquid or gas is used to drive the heat engines. It should be understood that thermoelectric generator illustrated in FIG. 14A is not limiting. All other thermoelectric generator configurations as discussed herein may be used.

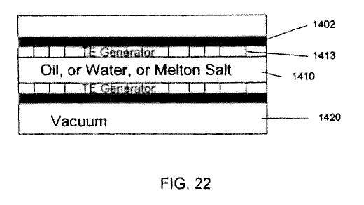

FIG. 21A illustrates presents a series of trough concentrators 2026 which may be used in power plants populated by STTE converters used in the cogeneration of solar thermoelectric energy and solar thermal energy in accordance with a preferred embodiment of the present invention. An evacuated tube 1420 passes through a reflective trough 2026 which reflects sunlight onto the tube. The details of an exemplary evacuated tube in accordance with the present invention is given in: http://www.schott.com/hungary/hungarian/download/ptr_{—}70_brochure.pdf and incorporated herein by reference. The thermoelectric generators as discussed previously will be thermally coupled to these tubes, and preferably situated inside the evacuated tube, as described in detail below, with the absorbers thermally linked to the hot side of the thermoelectric generator, e.g., as shown in FIG. 22.

The fluid exiting the trough through the tube has a temperature of about 40° C. The hot fluid generates electricity in a generator using a Rankine heat engine or steam cycle, as an example. Any suitable heat transfer fluid may be used, such as, but not limited to, water, oil, and melton salt. The hot-side 1412 and the cold-side 1411 of the thermoelectric converters 1413 can be operated at a constant temperature or a variable temperature.

FIG. 22 presents a side view of an individual STTE converter 1400 similar to that shown in FIG. 14A used in the cogeneration of solar thermoelectric energy and solar thermal energy that is used to drive pump using a Rankine cycle in accordance with a preferred embodiment of the present invention. FIG. 22 shows the thermoelectric converters 1413 distributed along the pipes 1410 carrying the same fluid used in the electric plant for power generation. The thermoelectric converters 1413 are formed above the pipes 1410 with respect to the location of the sun. The thermoelectric converters 1413 may fully or partially cover the pipes 1410. The pipes 1410 may have a flat shape, cylindrical shape, or any other reasonable geometric configuration. The pipes and converters may be located in a vacuum inside an outer shell or housing 1420. Different thermoelectric materials can be used along the length of the pipe or other conduit to take advantage of different fluid temperatures along the pipe line. For example, the inlet end of the fluid conduit has a larger temperature difference between the fluid and the thermoelectric converters than the outlet end of the conduit. Thus, thermoelectric converter materials used in thermal contact with the inlet end of the conduit provide for lower temperatures at the cold-side than thermoelectric materials at the outlet end of the conduit. The thermoelectric converters 1413 can operate effectively in pressures from vacuum levels to atmospheric pressure, potentially increasing solar electricity efficiency from 20% to 25-30%.

Tubular Modules with Planar Thermoelectric Devices

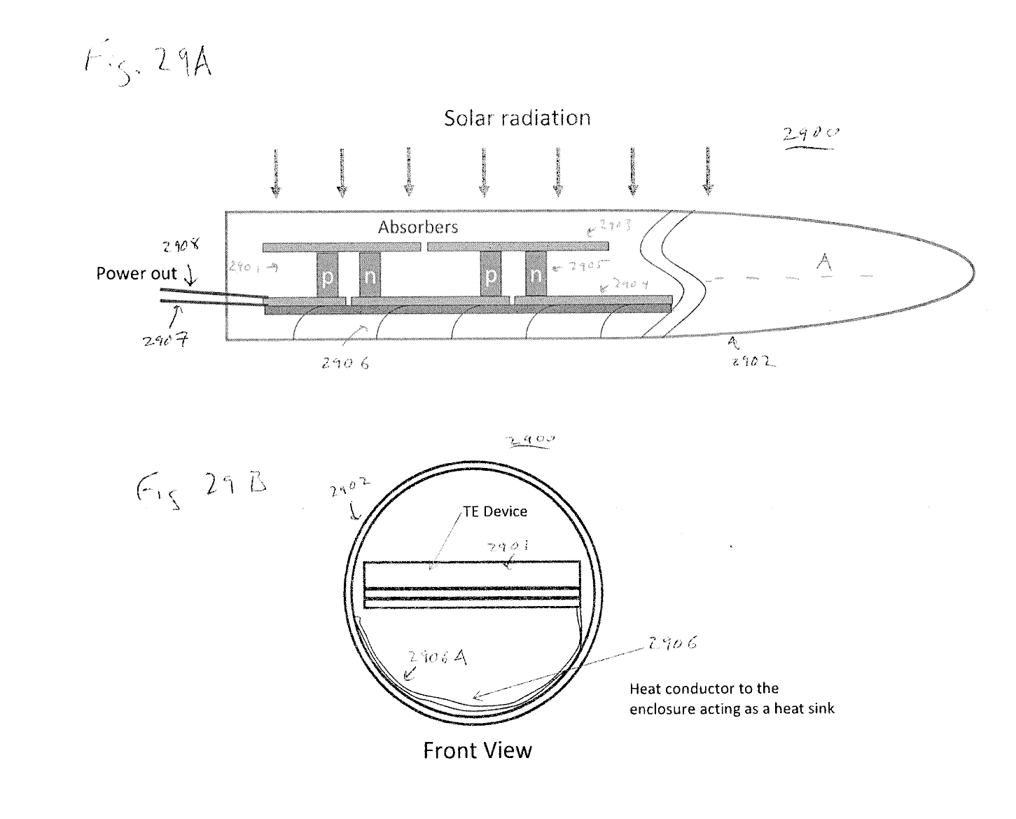

Referring to FIGS. 29A and 29B, in some embodiments, the solar energy generation module 2900 includes a planar thermoelectric device 2901 in an isolated (e.g., evacuated) environment in a tubular enclosure 2902 (e.g., a glass tube) that extends along a longitudinal axis A. As shown, the tubular enclosure is cylindrical, i.e. has a generally circular cross section, with a tapered end. However, in various embodiments, any elongated tubular shape may be used. In some embodiments, the tube has a substantially oval cross section. In other embodiments, the cross section my be square, rectangular, polygonal, irregular, etc. On or more of the ends of the tube may be a tapered end, a blunt end, a rounded end (e.g. including a hemispherical portion), etc.

Electrically conductive leads 2907 and 2908 are also depicted, which can provide appropriate electrical coupling within and/or between thermoelectric converters, and can be used to extract electrical energy generated by the converters 2905.

In some embodiments, the thermoelectric device 2901 is arranged in a substantially planar configuration. For example, in some embodiments, the separation between corresponding points on the top and bottom major surfaces of the device 2901 deviates by less than 10% over the extend of the device. In some embodiments, the device has a curvature of less that 10% of the thickness of the device 2901. Similar to the thermoelectric devices employed in flat panel embodiments (as discussed in detail above), the thermoelectric device 2901 includes a top (hot side) absorber 2903, a bottom (cold side) support structure 2904, and thermoelectric converters 2905 disposed therebetween (as shown, pairs of p-type and n-type legs). For some applications, e.g., those in which the solar generation module 2900 is used without a solar tracking system, a planar configurations is advantageous, as it may exhibit more uniform heating as the sun moves across the sky during the day and over the course of the year.

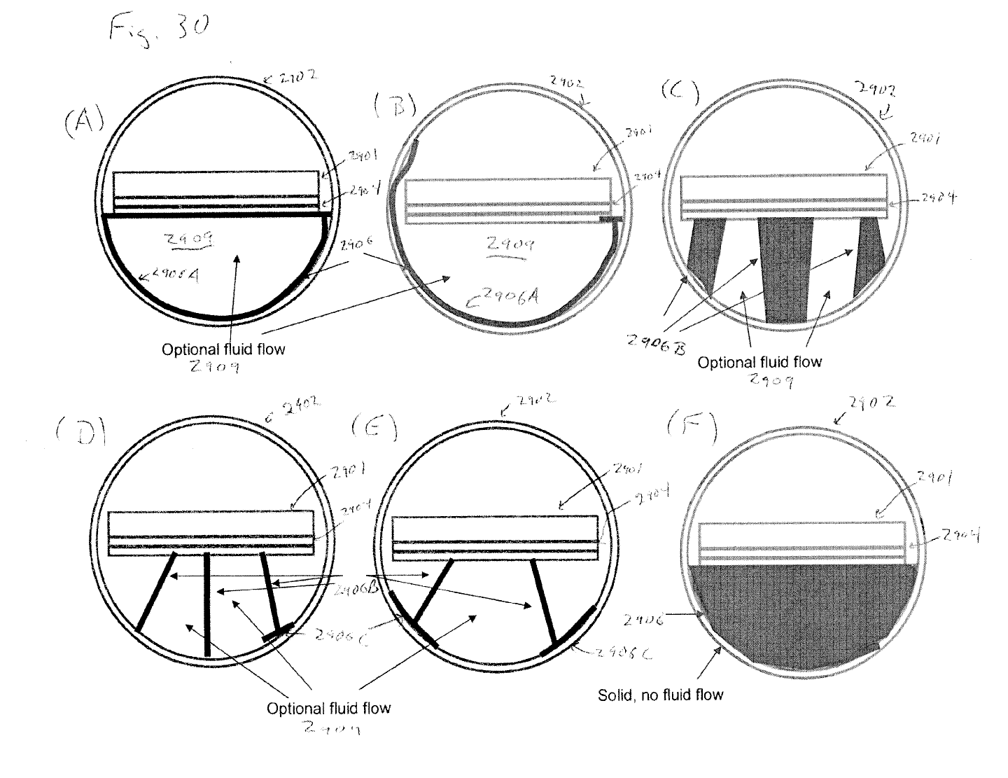

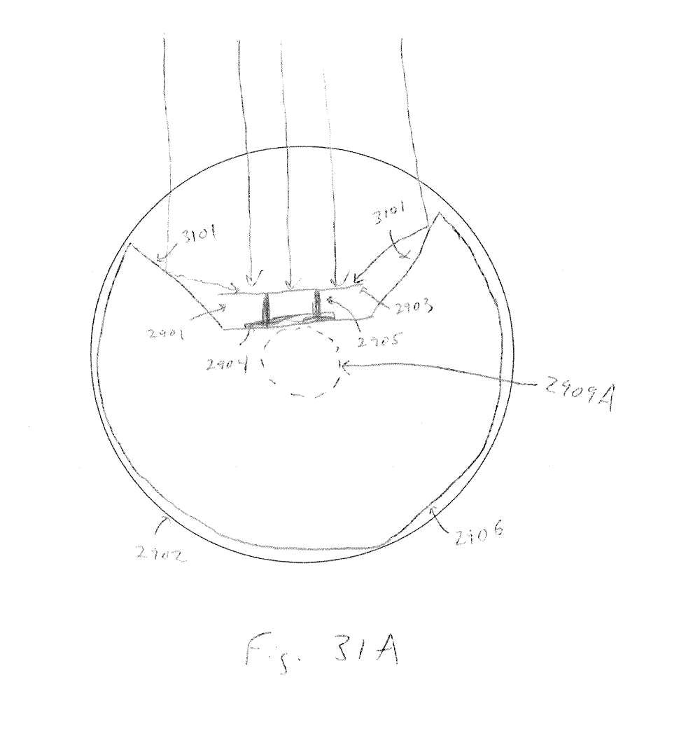

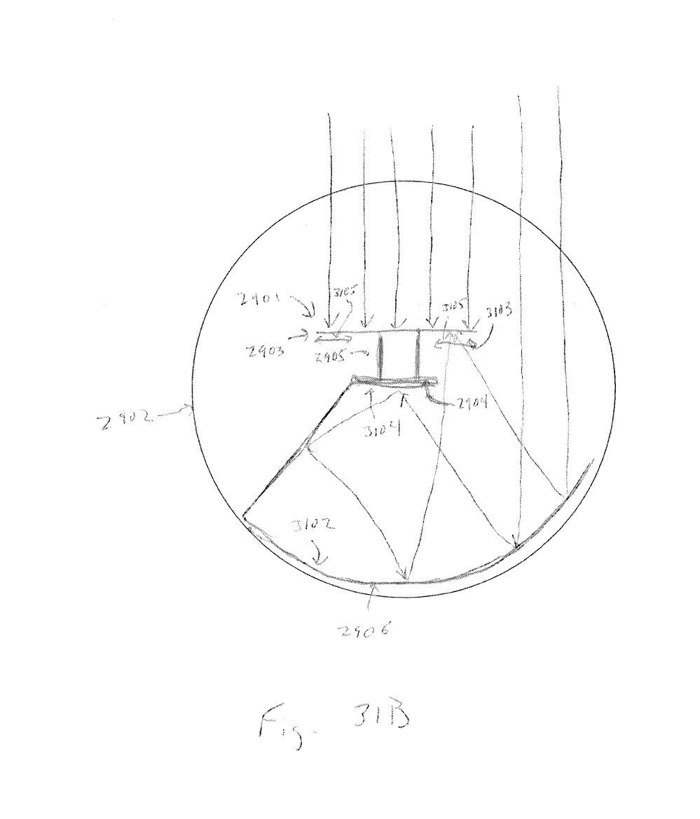

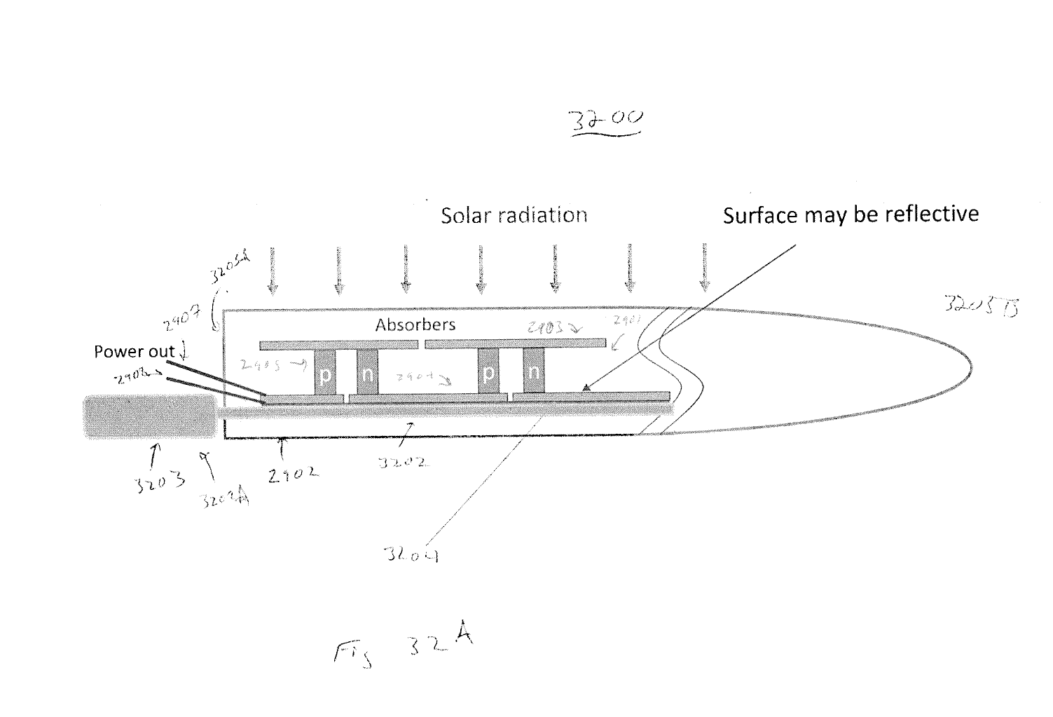

A heat conducting element 2906 extends between the support structure 2904 and the evacuated enclosure which transfer heat away from the support structure to the enclosure, thereby helping to maintain the temperature differential between the hot and cold sides of the thermoelectric converters 2905. For example, heat conducting element 2906 may include any thermally conductive material, such as a metal (e.g. copper) or metal coated member, extending from the support structure 2904 to the evacuated enclosure. The heat conducting element 2906 may provide mechanical support for the thermoelectric device 2901 within the enclosure 2902, e.g., as shown in FIGS. 29B and 30A through 30E. As shown in FIG. 30F, in some embodiments, the heat conducting element 2906 may be a solid member which substantially fills a portion (as shown, in the lower half) of the tubular enclosure, and does not allow for fluid flow.

As shown, the heat conducting element 2906 includes a curved portion 2906A which is conformal to a portion of the tubular enclosure 2902, e.g., as shown in FIGS. 29B, 30A, 30B, and 30F. Conformal means that the element portion physically contacts and assumes the shape of the surface. In some embodiments the heat conducting element 2906 may include a portion which is coated (e.g. metalized) directly on to the interior surface of the enclosure 2902. Such a coating may be formed and/or patterned using any suitable technique to provide electrically and/or thermally isolated portions. One technique includes plating (e.g., electroplating) or depositing (e.g. using chemical vapor deposition techniques) a material layer, and then using lithographic and etching processes to pattern the material layer.

In other embodiments, heat conducting element 2906 may contact the enclosure at one or more points or regions, e.g., as shown in FIGS. 30C, 30D, and 30E. For example, one or more “legs” 2906B may extend from the thermoelectric device to optional flat “foot” portions 2906C contacting the enclosure (e.g. the rightmost leg in FIG. 30D and both legs in FIG. 30E.). The foot portions may include regions coated or metallized onto the enclosure. There may be of any number of legs and they may have any suitable shape (e.g. thin, thick, tapered, irregular, etc.). In some embodiments the legs may extend along the direction of the longitudinal axis A, thereby forming fin-like members.

FIGS. 30A-30E show exemplary heat conducting element configurations. In FIG. 30A, the heat conducting element 2906 is an elongated semi-cylindrical element having a curved portion conformal to the bottom half of enclosure 2902. In FIG. 30B, the heat conducting element 2906 has a curved portion 2906A which is attached to a side of thermoelectric device 2901 and is conformal to the bottom half of enclosure 2902. In FIG. 30C, the heat conducting element 2906 includes three thick legs 2906B which extend from thermoelectric device 2901 to enclosure 2902. In FIG. 30D, the heat conducting element 2906 includes three thin legs 2906B which extend from thermoelectric device 2901 to enclosure 2902. The rightmost leg includes a foot portion 2906C contacting the enclosure. In FIG. 30E, the heat conducting element 2906 includes two thin legs 2906B which extend from thermoelectric device 2901 to enclosure 2902. All legs include a foot portion 2906C contacting the enclosure.

In some embodiments, a fluid may flow through or near heat conducting element 2906 to transfer heat away from the element. In some embodiments, one or more heat conducting elements may form a fluid flow conduit 2909 within the enclosure 2902. The fluid flow conduit may be closed (e.g., sealed fluid tight), so as to thermally and/or physically isolate the hot side top absorber 2903 from the fluid. As described herein, the heat transferred to the fluid may be extracted from the fluid as desired for applications including electrical power generation, home heating, etc.

FIGS. 30A-30E show exemplary fluid flow configurations. In FIG. 30A, the heat conducting element 2906 forms an elongated semi-cylindrical shaped conduit 2909. In FIG. 30B, the heat conducting element 2906 forms a fluid flow conduit 2909 bounded by curved portion 2906A and the bottom surface of the thermoelectric device 2901. In FIG. 30C, two fluid flow conduits 2909 are formed between pairs of the three thick legs 2906B. In FIG. 30D, two fluid flow conduits 2909 are formed between pairs of the three thin legs 2906B. In FIG. 30E, one fluid flow conduit 2909 is formed between the pair of thin legs 2906B. In various embodiments, any other suitable fluid flow conduit geometry may be used. In general, conduits 2909 may be partially or completely bound by portions of heat conducting element 2906. In other embodiments, the conduit 2909 may be a separate tube in direct or indirect thermal contact with heat conducting element 2906 and/or the cold side of thermoelectric device 2901.

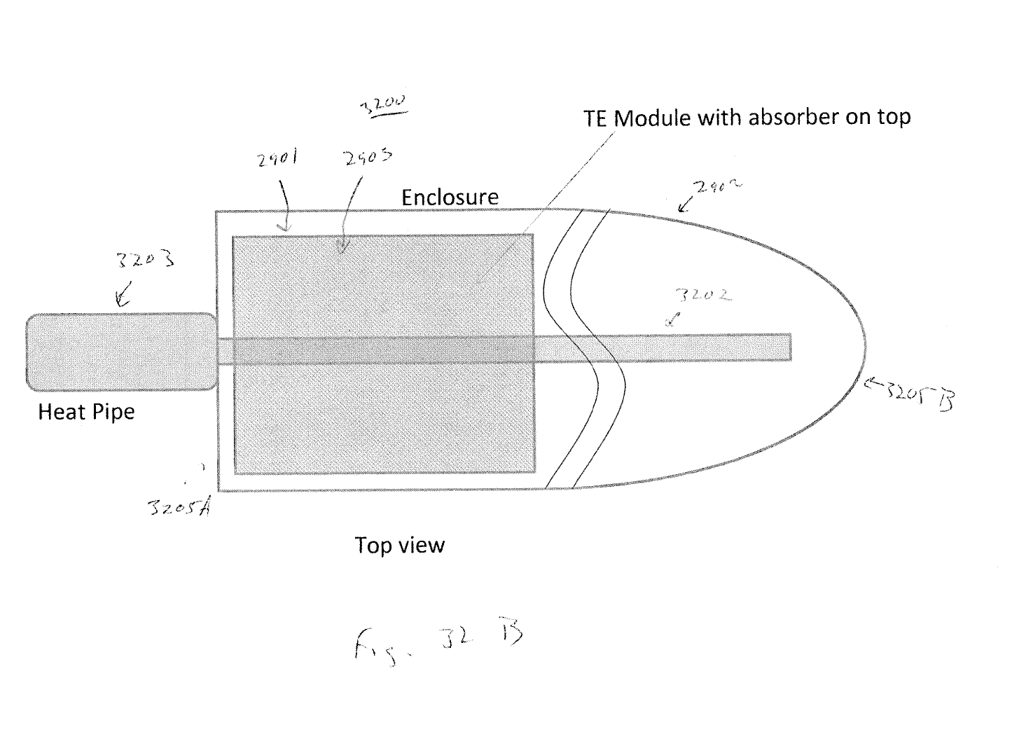

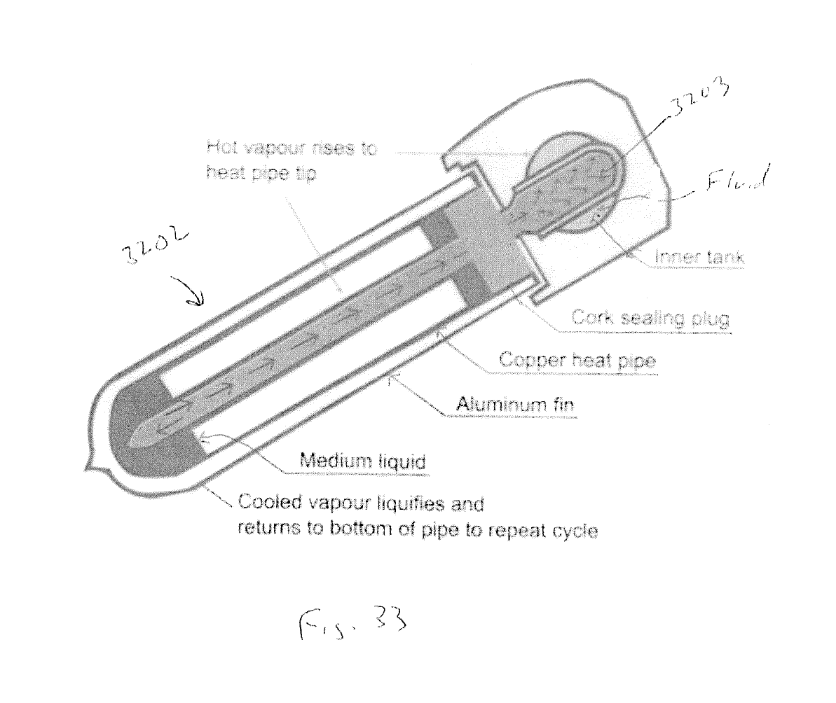

Referring to FIGS. 31A and 31B, in some embodiments, at least a portion of the heat conducting element 2906 may include one or more optical concentrating elements which concentrate solar radiation onto the absorber 2903 (e.g. as indicated by arrowed rays in FIGS. 31A and 31B). The optical concentrating element may include reflective, refractive, and/or diffractive elements.

Referring to FIG. 31A, heat conducting element 2906 includes a trough shaped portion 3101 with reflective sidewalls which concentrate incident solar radiation onto the top surface of absorber 2903. The trough shaped portion 3101 may have flat or curved sidewalls. In some embodiments, the trough may be formed in a parabolic concentrator or compound parabolic concentrator configuration, or any other suitable concentrator configuration known in the art.

Accordingly, the heat conducting element 2906 includes a first curved portion located adjacent and substantially conformal to a curved interior surface of the enclosure. Heat conducting element 2906 includes an optical concentrating element including second reflective portions (the sidewalls of through shaped portion 3101) of the heat conducting element located adjacent to at least one side of the at least one thermoelectric converter. These first and the second portions of the heat conducting element 2906 are directly or indirectly thermally connected to each other.

Referring to FIG. 31B, in some embodiments, the heat conducting element 2906 includes a first reflective curved portion 3102 located adjacent and substantially conformal to a curved interior surface of the enclosure. In the configuration shown, the area of the support structure 2904 is substantially smaller (e.g., at least two times smaller) than an area of the radiation absorber 2903, such that radiation reflected by the first reflective curved portion 3102 (i.e. similar to curved portion 2906A in the examples above, but including a reflective surface) is incident onto a portion 3105 of the back surface 3103 of the absorber 2903 which is exposed to the optical concentrating element beyond the support structure 2904.

In various embodiments, the reflective portions 3101 and 3102 of the heat conducting element 2906 may be made of a reflective metal, or coated with a reflective metal layer or film.

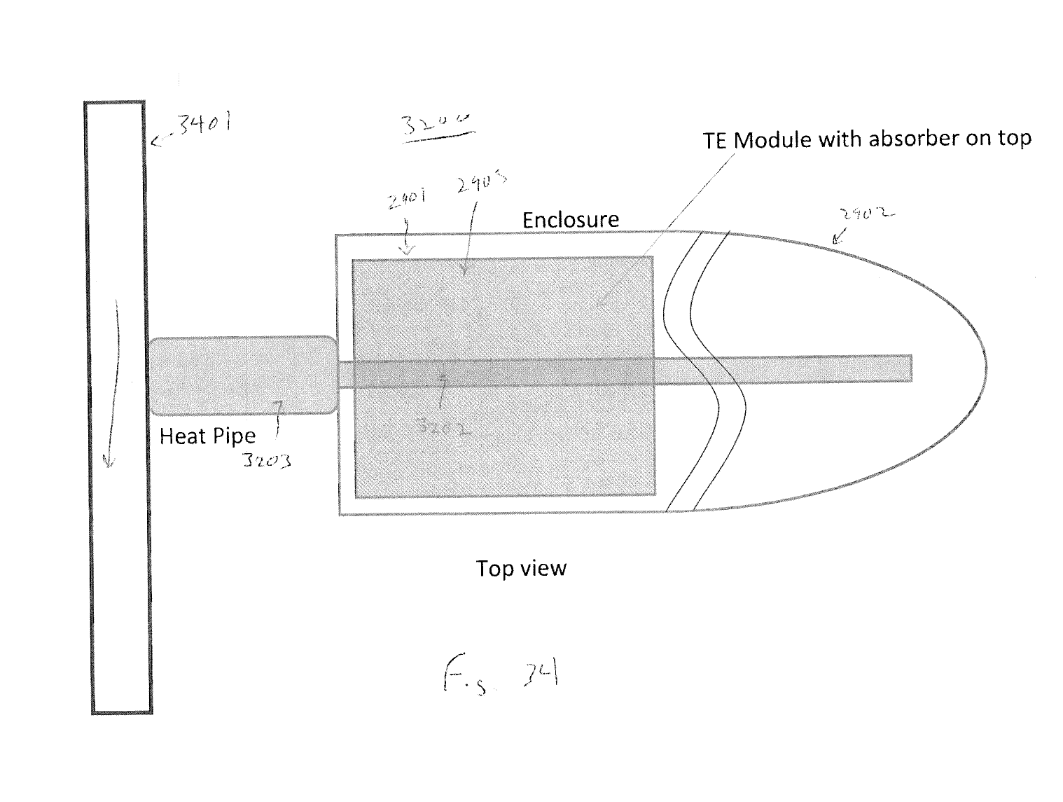

Referring to FIGS. 32A and 32B in some embodiments, solar energy generation module 3200 includes a planar thermoelectric device 2901 in an isolated (e.g., evacuated) environment in a tubular enclosure 2902 (e.g., a glass tube). As shown, the tubular enclosure is cylindrical with a tapered end. However, in various embodiments, any elongated tubular shape may be used. In some embodiments, the tube has a substantially circular or oval cross section. In other embodiments, the cross section my be square, rectangular, polygonal, irregular, etc. On or more of the ends of the tube may be a tapered end, a blunt end, a rounded end (e.g. including a hemispherical portion), etc.

The thermoelectric device 2901 is arranged in a substantially planar configuration. Similar to the thermoelectric devices employed in flat panel embodiments (as discussed in detail above), the thermoelectric device 2901 includes a top (hot side) absorber 2903, a bottom (cold side) support structure 2904, and thermoelectric converters 2905 disposed therebetween (as shown, pairs of p-type and n-type legs).

A fluid filled heat transfer conduit, as shown, such as a heat pipe heat pipe 3202, is located at least partially within the evacuated enclosure 2902 and in thermal contact with the support structure 2904 and operates to transfer heat from the support structure to the fluid. The fluid may include water or any other suitable heat transfer fluid. In some embodiments heat pipe 3202 is a metal (e.g., copper) pipe. In other embodiments, heat pipe 3202 may be made of glass (as discussed in detail below), or other materials. Some embodiments may include an electrically non-conductive but thermally conductive material 3204 between support structure 2904 and the heat pipe 3202 which electrically isolates the heat pipe 3202.

In some embodiments, heat pipe 3202 mechanically supports the thermoelectric device 2901 within the enclosure 2902, such that a supporting heat conducting element 2906 may be optionally omitted. Some embodiments may further include one or more heat conducting elements (not shown) of the type described above which provides thermal contact between the support structure.

In such embodiments, the evacuated enclosure 2902 may include a first elongated tube extending along a longitudinal axis having an inner surface, an outer surface, a first end portion 3205A and a second end portion 3205B. The fluid filled heat transfer conduit, e.g., heat pipe 3202, includes a second elongated tube having an inner surface and an outer surface. The second elongated tube is least partially disposed within the first elongated tube. An end portion 3202A of the second elongated tube extends out of the first elongated glass tube through the first end portion 3205A of the first elongated tube.

In substantially the same manner as described above with respect to flat panel solar modules, the heat pipe 3202 acts as a heat sink for the cold side support surface 2904 of the thermoelectric device 2901. An end portion 3202A of the heat pipe 3202 extends out of the enclosure 2902 to allow heat to be extracted from the fluid for use in heating applications, electrical or mechanical energy generation applications, etc. For example, as shown, the end portion 3202A of heat pipe 3202 extending from the enclosure 2902 terminates with a condenser bulb 3203.

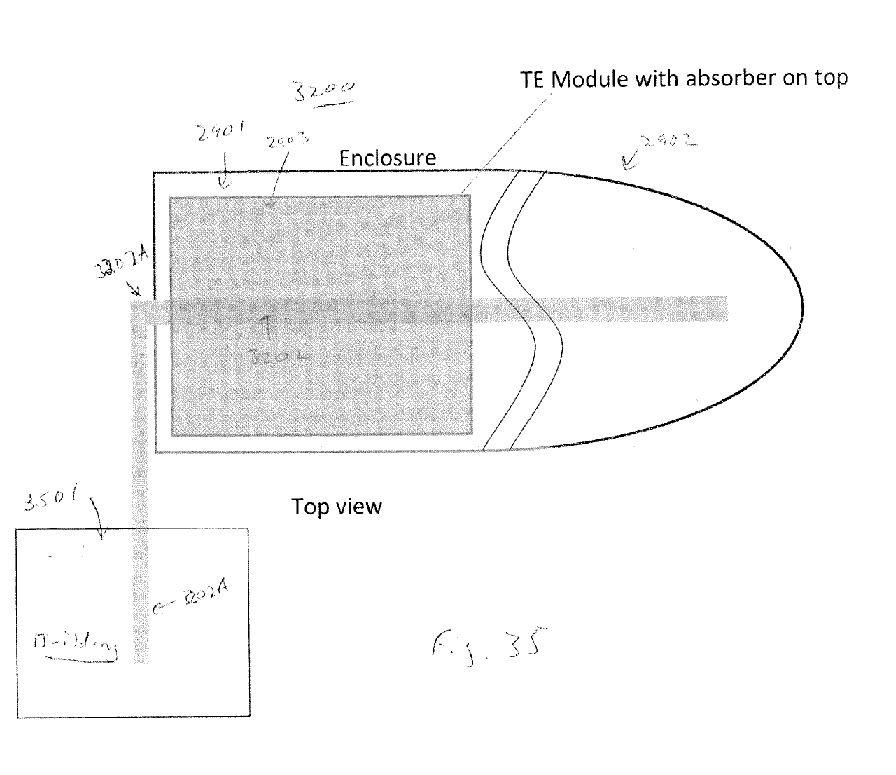

FIG. 33 illustrates the operation of an exemplary heat pipe 3202 as a heat extraction element. As the heat pipe is heated, either by absorbing heat from support structure or directly by incident solar radiation impinging on the pipe, a liquid medium inside the pipe is converted to a hot vapor which moves towards the end of the pipe which includes condenser bulb 3203. In the bulb, the hot vapor expands and cools, transferring heat to the surroundings of the bulb (as shown, warming fluid in a fluid filled tank). The cooled vapor condenses into liquid form and flows away from the end of the pipe having the bulb to repeat the cycle. In some embodiments, the condenser bulb 3203 is positioned higher that the opposite end of the heat pipe 3202, such that gravity assists the movement of condense liquid away from bulb 3203.

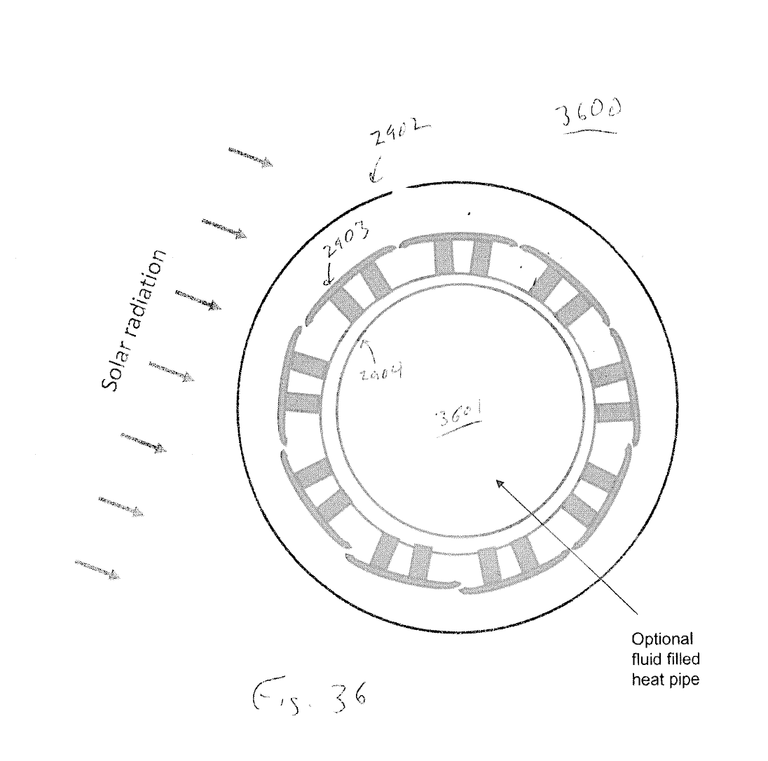

Referring to FIG. 34, in one embodiment, condenser bulb 3203 is in thermal contact with a hot water pipe or tank 3401 (e.g., of a building), such that the fluid in bulb 3203 is adapted to heat water in the hot water pipe or tank. The hot water tank may be located inside the building or outside of the building (e.g., on a roof of the building). Referring to FIG. 35, in another embodiment, the condenser bulb 3203 is omitted, and an end 3202A of heat pipe 3202 extending out of the enclosure 3202 forms a heating pipe (e.g., a hot water pipe) of a building 3501.

Referring back to FIG. 32A, in some embodiments both enclosure 2902 and heat pipe 3202 may be formed of glass. An end 3202A of heat pipe 3202 extends out and end portion 3205A of enclosure 3202. Where the glass heat pipe 3202 pierces through the end portion 3205A an air tight glass to glass seal may be formed (e.g., by melting the glass tubes together) which maintains the vacuum in enclosure 2902. In some embodiments, the evacuated enclosure 2902 is sealed using only glass to glass sealing.

The glass to glass sealing may be provided in any device configuration described above, including the configuration of FIGS. 32A, 32B, 34 and 35, as well as FIG. 37 (as will be described below).

In any of the embodiments described herein featuring a heat pipe or other heat transfer conduit, the thermoelectric converter (e.g., 14 in FIGS. 1 and 2905 in FIG. 32A) may be omitted, and heat transferred directly from an absorber layer to a fluid in the pipe/conduit. Furthermore, if desired, the absorber layer (e.g., 12 in FIGS. 1 and 2903 in FIG. 32A) may also be omitted in addition to omitting the thermoelectric converter.

In these embodiments, it is preferred to construct the heat pipe/conduit from a glass. Thus, in these embodiments, the heat pipe comprises an inner glass tube containing a heat transfer fluid, which is enclosed inside an outer glass enclosure tube. A vacuum is provided in the space between the outer glass enclosure tube and the inner glass heat pipe. As shown in FIGS. 32A, 32B, 34 and 35, in the embodiments where the thermoelectric converter is omitted, the inner glass heat pipe protrudes through the end of the outer glass tube and only glass to glass sealing is used as described above.

Preferably, in the embodiments that omit the thermoelectric converter, the radiation absorber is present in the enclosure between the inner enclosure surface and the second tube's outer surface. As in the prior embodiments, the front surface of the absorber is adapted for exposure to solar radiation so as to generate heat, and the rear surface is thermally coupled to the second elongated glass tube. The radiation absorber may have any suitable configuration, such as a planar unit described in the embodiments above. Alternatively, it may comprise a curved conformal layer or foil which conforms to an outer surface of the second elongated glass tube. The conformal layer may be deposited by any suitable deposition method, such as plating, CVD, sputtering, etc. The foil may be prefabricated and wrapped around the tube. If desired, the radiation absorber may direct contacts the outer surface of the second elongated glass tube.

In some alternative embodiments, a thermally conductive layer or coating is formed on the outer surface of the glass heat pipe. In the embodiments containing the support structure and the thermoelectric converters, this layer provides thermal contact between the heat pipe and the support structure 2904. In the embodiments lacking the thermoelectric converters and the support structure, this layer provides thermal contact between the heat pipe and the absorber.

In cases where the thermal expansion of the conductive material is not well matched to that of glass (e.g., when using a metallic material such as copper) at least one of the conductive coating and the absorber may be designed to provide stress relief during thermal expansion and contraction of the glass heat pipe 3202. For example, at least one of the conductive coating and the absorber may be formed as multiple distinct sections.

In various embodiments, the heat pipe/conduit may take any suitable form including a copper pipe, a glass pipe or tube (e.g., as described above), etc. The pipe/conduit may be filled with any suitable type of heat transfer fluid, such as water or oil. The heated fluid may be used in any of a variety of applications, including home heating, electrical generation (e.g. using a steam powered turbine), etc.

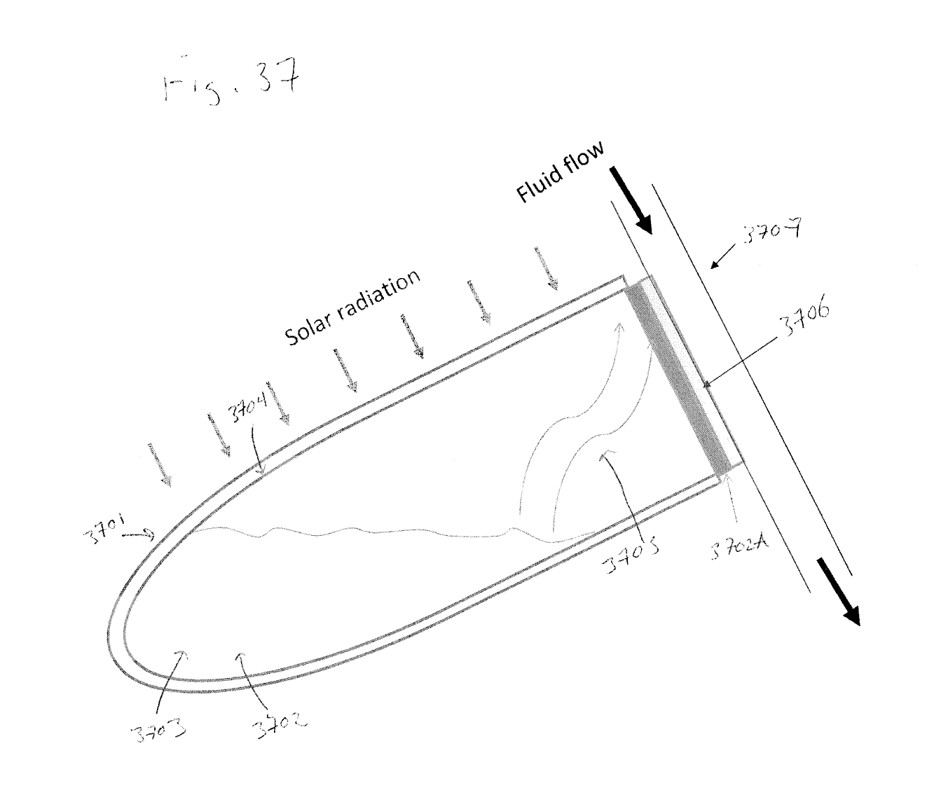

Although several embodiments have been described featuring a planar shaped thermoelectric device located within an tubular evacuated enclosure, in other embodiments featuring thermoelectric devices with other shapes my be used. For example, FIG. 36 shows a solar conversion module 3600 in which thermoelectric device 2901 located within tubular enclosure 2902 is cylindrically shaped. Absorber 2903 and support structure 2904 are formed, respectively, as outer and inner concentric curved members which follow the contour of tubular enclosure 2902, with thermoelectric converters 2905 disposed therebetween. Solar radiation incident on the absorber 2903 will heat the outer absorber, creating a temperature differential across the thermoelectric converters 2905 to the inner support structure 2904. In some embodiments, a fluid filled heat transfer conduit 3601 may be located within inner support structure 2904 to carry away heat, as described above.

Heat Pipe with External Thermoelectric Device

Referring to FIG. 37, a solar conversion module 3700 includes a transparent evacuated tubular enclosure 3701. The enclosure contains an inner tube 3702 at least partially filled with a liquid 3703. At least a portion of the outer surface of the inner tube is covered with an absorber layer 3704, e.g., having the properties of various absorbers described herein. Solar radiation incident on the absorber layer 3704 heats the liquid 3703 inside inner tube 3702 forming hot vapor 3705, which moves to the end portion 3702A of the inner tube 3702. The end portion of inner tube 3702 may be in thermal contact with the hot side of a thermoelectric device 3706. Device 3706 may be omitted if desired. Heat from the hot vapor 3705 is transferred to the hot side of the thermoelectric device 3706, providing the temperature gradient necessary to produce electric power. In some embodiments, the cold side of the thermoelectric device 3706 may be in thermal contact with a heat sink, such a heat transfer fluid filled conduit 3707 which removes heat from the cold side of the device. As described in detail above, the heat transferred to the fluid (or otherwise removed from the device 3706) may be employed e.g., for heating, electricity generation, etc.

### Conversion Performance

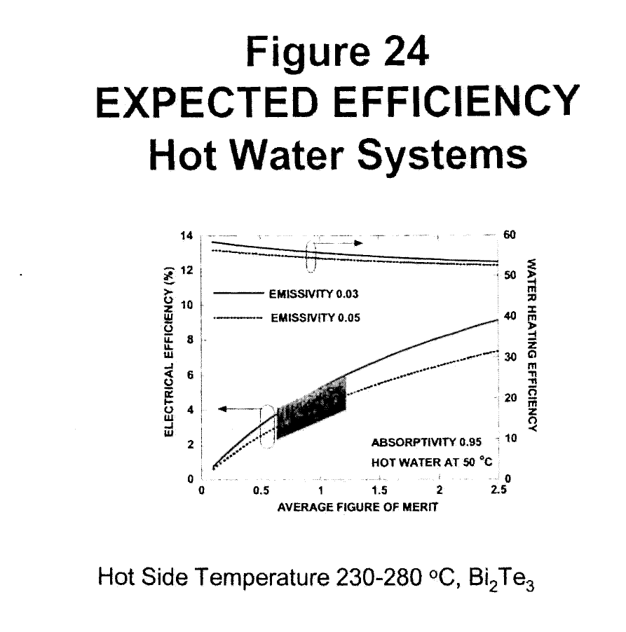

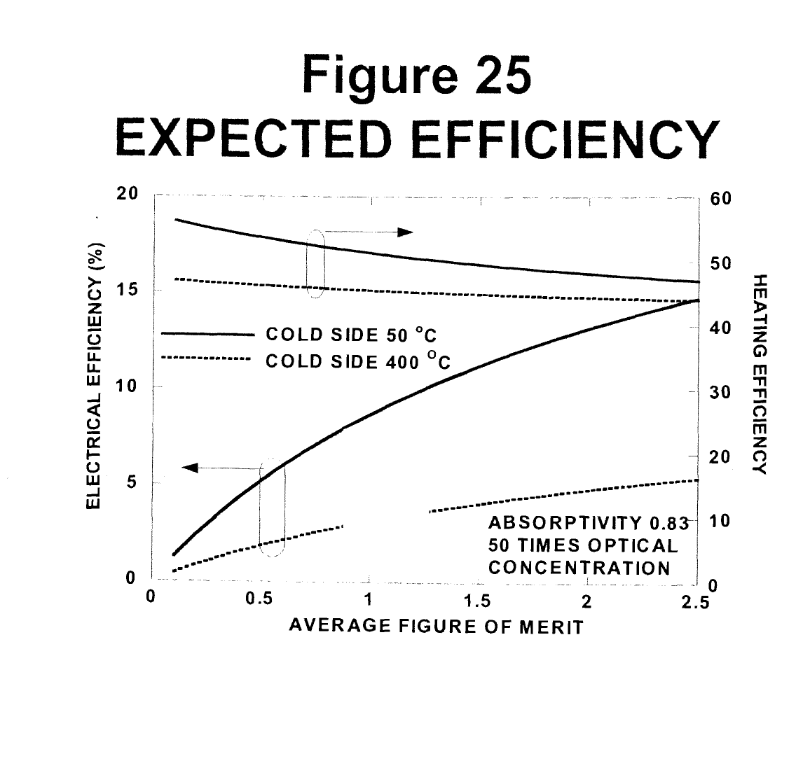

FIG. 24 shows examples of modeling results of the combined solar thermoelectric generator with hot water system for a system without optical concentration. The left vertical axis shows electrical generation efficiency and right vertical axis shows water heating efficiency. These efficiency values depend on the hot water temperature, and emissivity of the selective absorbers, in addition to other properties. With low (thermal) emissivity surfaces, higher efficiency can be reached. For example, for emissivity values of 0.03 and 0.05, electrical efficiency values of about 4 to about 6% and heating efficiency values of about 50 to about 60% may be achieved for ZT values of 1 to 1.5. FIG. 25 shows exampled of modeling results of combined solar thermoelectric generator with the cold side temperature varying from 50° C. to 400° C., similar to that experienced by fluids flowing in the pipes in trough solar thermal plant. For example, for cold side temperatures described above, the electrical efficiency values of about 3 to about 10% and heating efficiency values of about 45 to about 55% may be achieved for ZT values of 1 to 1.5. Depending on ZT values and other parameters, the thermoelectric generators can generate 3-10% additional electricity and the rest of heat can be used to drive mechanical-based power conversion cycles. It is understood that these are only examples, and for each applications, optimization of the system can be realized to realize maximum gain in efficiency and cost of electricity generation.

While the invention has been described in connection with the specific embodiments thereof, it will be understood that it is capable of further modification. Furthermore, this application is intended to cover any variations, uses, or adaptations of the invention, including such departures from the present disclosure as come within known or customary practice in the art to which the invention pertains, and as fall within the scope of the appended claims. Each feature of each embodiment may be used in any combination with any one or more features from the same embodiment and/or from one or more other embodiments.

All publications, patents, and patent applications mentioned in this specification are herein incorporated by reference to the same extent as if each individual publication, patent, or patent application was specifically and individually indicated to be incorporated by reference.

The entire contents of International Patent Application Number PCT/US2008/006441 filed May 20, 2008 are hereby incorporated by reference herein.

1. An apparatus comprising:
an evacuated enclosure which comprises a tubular member extending along a longitudinal axis;
a radiation absorber disposed in the enclosure and having a front surface and a back surface, the front surface being adapted for exposure to solar radiation so as to generate heat;
at least one thermoelectric converter disposed in the enclosure and thermally coupled to the absorber, the converter having a high-temperature end to receive at least a portion of the generated heat, such that a temperature differential is achieved across the at least one thermoelectric converter;
a support structure disposed in the enclosure coupled to a low-temperature end of the thermoelectric converter, wherein the support structure removes heat from a low-temperature end of the thermoelectric converter; and
a heat conducting element extending between the support structure and the evacuated enclosure and adapted to transfer heat from the support structure to the enclosure; and
wherein the absorber, the at least one thermoelectric converter, and the support structure are arranged as a planar unit located within the tubular member.

2. The apparatus of claim 1, wherein the support structure comprises an inner surface adapted to face the back surface of the radiation absorber, the enclosure comprises a curved interior surface, and the heat conducting element comprises a curved portion located adjacent and substantially conformal to the curved interior surface of the enclosure, and the heat conducting element extends from the planar unit to the enclosure to mechanically support the planar unit in the enclosure.

3. The apparatus of claim 1, wherein at least a portion of the heat conducting element comprises an optical concentrating element configured to concentrate incident radiation onto the radiation absorber.

4. The apparatus of claim 3, wherein:
the optical concentrating element comprises a reflective curved portion of the heat conducting element located adjacent and substantially conformal to a curved interior surface of the enclosure; and
an area of the support structure is substantially smaller than an area of the radiation absorber, such that radiation reflected by the optical concentrating element is incident onto a portion of the back surface of the radiation absorber which is exposed to the optical concentrating element beyond the support structure.

5. The apparatus of claim 3, wherein:
the heat conducting element comprises a first curved portion located adjacent and substantially conformal to a curved interior surface of the enclosure;
the optical concentrating element comprises a second reflective portion of the heat conducting element located adjacent to at least one side of the at least one thermoelectric converter;
the first and the second portions of the heat conducting element are directly or indirectly thermally connected to each other.

6. The apparatus of claim 1, further comprising a fluid filled heat transfer conduit in thermal contact with at least one of the support structure or the heat conducting element and adapted to transfer heat from the at least one of the support structure or the heat conducting element to the fluid.

7. The apparatus of claim 1, wherein the heat conducting element comprises a fluid filled heat transfer conduit in thermal contact with the support structure and adapted to transfer heat from the support structure to the fluid.

8. (canceled)

9. An apparatus comprising:
an evacuated enclosure;
a radiation absorber disposed in the enclosure and having a front surface and a back surface, the front surface being adapted for exposure to solar radiation so as to generate heat,
at least one thermoelectric converter disposed in the enclosure and thermally coupled to the absorber, the converter having a high-temperature end to receive at least a portion of the generated heat, such that a temperature differential is achieved across the at least one thermoelectric converter;
a support structure disposed in the enclosure coupled to a low-temperature end of the thermoelectric converter, wherein the support structure removes heat from a low-temperature end of the thermoelectric converter; and
a fluid filled heat transfer conduit located at least partially within the evacuated enclosure and in thermal contact with the support structure and adapted to transfer heat from the support structure to the fluid.

10. The apparatus of claim 9, wherein:
the support structure comprises an inner surface adapted to face the back surface of the radiation absorber;
the evacuated enclosure comprises a tubular member extending along a longitudinal axis; and
the absorber, the at least one thermoelectric converter, and the support structure are arranged as a planar unit within the tubular member.

11. The apparatus of claim 9, further comprising a heat conducting element extending between the support structure and the evacuated enclosure and adapted to transfer heat from the support structure to the enclosure.

12. The apparatus of claim 9, wherein:
the evacuated enclosure comprises a first elongated glass tube extending along a longitudinal axis, the first elongated glass tube having an inner surface, an outer surface, a first end portion and a second end portion;
the fluid filled heat transfer conduit comprises a second elongated glass tube having an inner surface and an outer surface;
the second elongated glass tube is least partially disposed within the first elongated glass tube; and
an end portion of second elongated glass tube extends out of the first elongated glass tube through at least one of the first and the second end portions of the first elongated glass tube.

13. The apparatus of claim 12, further comprising at least one air tight glass to glass seal between the first and second elongated glass tubes sealing the evacuated enclosure to form an evacuated region between the outer surface of the second elongated glass tube and the inner surface of the first elongated glass tube.

14. The apparatus of claim 12, wherein the evacuated enclosure is sealed using only glass to glass sealing.

15. The apparatus of claim 12, further comprising a heat transfer element located on the end portion of the second elongated glass tube, the heat transfer element is adapted to extract heat from the fluid.

16. The apparatus of claim 15, wherein the heat transfer element comprises a condenser bulb.

17. The apparatus of claim 12, further comprising a thermally conductive coating on the outer surface of the second tube providing thermal contact between the second tube and the support structure.

18. The apparatus of claim 17, wherein the thermally conductive coating comprises a metal coating having one or more distinct sections to provide stress relief during thermal expansion and contraction of the second elongated glass tube.

19. The apparatus of claim 12, wherein:
the end portion of second elongated glass tube comprises a hot water pipe which extends into building; and
the fluid comprises water.

20. The apparatus of claim 12, wherein the end portion of second elongated glass tube is in thermal communication with a hot water pipe or tank of a building, such that the fluid is adapted to heat water in the hot water pipe.

21-51. (canceled)
